(19) United States
(12) Patent Application Publication
(10) Pub. No.: US 2020/0393761 A1
(43) Pub. Date: Dec. 17, 2020

(54) RADIATION-SENSITIVE RESIN COMPOSITION AND RESIST PATTERN-FORMING METHOD

(71) Applicant: JSR CORPORATION, Tokyo (JP)

(72) Inventors: Katsuaki NISHIKORI, Tokyo (JP); Ken MARUYAMA, Tokyo (JP); Kazuki KASAHARA, Tokyo (JP); Tsuyoshi FURUKAWA, Tokyo (JP); Natsuko KINOSHITA, Tokyo (JP)

(73) Assignee: JSR CORPORATION, Tokyo (JP)

(21) Appl. No.: 16/897,326

(22) Filed: Jun. 10, 2020

(30) Foreign Application Priority Data
Jun. 14, 2019 (JP) 2019-111487
Apr. 20, 2020 (JP) 2020-074996

(51) Int. Cl. G03F 7/039; G03F 7/004; G03F 7/038; G03F 7/16; G03F 7/20; G03F 7/32; C08F 212/14; C08F 220/18

(52) U.S. Cl. CPC G03F 7/039; G03F 7/0045; G03F 7/038; G03F 7/162; C08F 220/1808; G03F 7/2004; G03F 7/322; C08F 212/22; C08F 220/1806; G03F 7/168

(57) ABSTRACT

A radiation-sensitive resin composition includes a polymer, a radiation-sensitive acid generator, and a compound represented by formula (2). The polymer includes a first structural unit including a phenolic hydroxyl group, a second structural unit including a group represented by formula (1), and a third structural unit including an acid-labile group. In the formula (1), R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, wherein at least one of R¹, R², R³, R⁴, R⁵, and R⁶ represents a fluorine atom or a fluorinated hydrocarbon group; R^{A} represents a hydrogen atom or a monovalent organic group having 1 to 20 carbon atoms; and * denotes a binding site to a part other than the group represented by the formula (1).

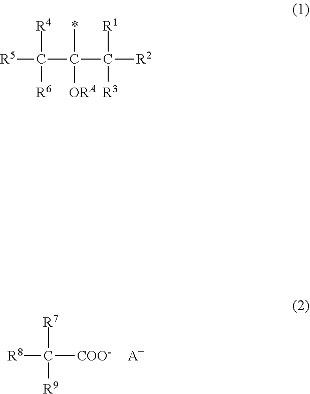

### CROSS-REFERENCE TO RELATED APPLICATIONS

The present application claims priority to Japanese patent application No. 2019-111487, filed Jun. 14, 2019 and to Japanese patent application No. 2020-074996, filed Apr. 20, 2020. The contents of these applications are incorporated herein by reference in their entirety.

### BACKGROUND OF THE INVENTION

### Field of the Invention

The present invention relates to a radiation-sensitive resin composition and a resist pattern-forming method.

### Discussion of the Background

A radiation-sensitive resin composition for use in microfabrication by lithography generates an acid at a light-exposed region upon irradiation with a radioactive ray, e.g., an electromagnetic wave such as a far ultraviolet ray such as an ArF excimer laser beam (wavelength of 193 nm), a KrF excimer laser beam (wavelength of 248 nm), etc., an extreme ultraviolet ray (EUV) (wavelength of 13.5 nm), or a charged particle ray such as an electron beam. A chemical reaction in which the acid serves as a catalyst causes a difference in rates of dissolution in a developer solution, between light-exposed regions and light-unexposed regions, whereby a resist pattern is formed on a substrate.

Such a radiation-sensitive resin composition is required not only to have favorable sensitivity to exposure light such as an extreme ultraviolet ray and an electron beam, but also to have superiority with regard to LWR (Line Width Roughness) performance, which indicates line width uniformity.

To meet such requirements, types, molecular structures, and the like of polymers and other components which may be used in radiation-sensitive resin compositions have been investigated, and combinations thereof have been further investigated in detail (see Japanese Unexamined Patent Publication, Publication Nos. 2009-244805, 2004-012510, and 2017-141373).

Along with further miniaturization of resist patterns, slight fluctuations in exposure and development conditions have come to exert an increasingly larger effect on configurations and generation of defects of resist patterns. Thus, a radiation-sensitive resin composition with a broad process window (a high process latitude) which enables absorption of such slight fluctuations in process conditions is also required.

### SUMMARY OF THE INVENTION

According to an aspect of the present invention, a radiation-sensitive resin composition includes a polymer, a radiation-sensitive acid generator, and a compound represented by formula (2). The polymer includes a first structural unit including a phenolic hydroxyl group, a second structural unit including a group represented by formula (1), and a third structural unit including an acid-labile group.

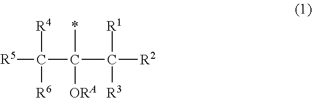

In the formula (1), R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, wherein at least one of R¹, R², R³, R⁴, R⁵, and R⁶ represents a fluorine atom or a fluorinated hydrocarbon group; R^{A} represents a hydrogen atom or a monovalent organic group having 1 to 20 carbon atoms; and * denotes a binding site to a part other than the group represented by the formula (1) in the second structural unit.

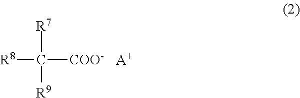

In the formula (2), R⁷, R⁸, and R⁹ each independently represent a hydrogen atom, a fluorine atom, or a monovalent organic group having 1 to 40 carbon atoms, and optionally two or more of R⁷, R⁸, and R⁹ taken together represent a part of a ring structure having 3 to 20 ring atoms together with the carbon atom to which the two or more of R⁷, R⁸, and R⁹ bond; and A⁺ represents a monovalent radiation-sensitive onium cation.

According to another aspect of the present invention, a resist pattern-forming method includes applying a radiation-sensitive resin composition directly or indirectly on a substrate to form a resist film directly or indirectly on the substrate. The resist film is exposed. The resist film exposed is developed. The radiation-sensitive resin composition includes a polymer, a radiation-sensitive acid generator, and a compound represented by formula (2). The polymer includes a first structural unit including a phenolic hydroxyl group, a second structural unit including a group represented by formula (1), and a third structural unit including an acid-labile group.

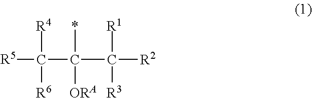

In the formula (1), R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, and at least one of R¹, R², R³, R⁴, R⁵, and R⁶ represents a fluorine atom or a fluorinated hydrocarbon group; R^{A} represents a hydrogen atom or a monovalent organic group having 1 to 20 carbon atoms; and * denotes a binding site to a part other than the group represented by the formula (1) in the second structural unit.

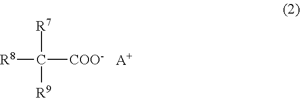

In the formula (2), R⁷, R⁸, and R⁹ each independently represent a hydrogen atom, a fluorine atom, or a monovalent organic group having 1 to 40 carbon atoms, and optionally two or more of R⁷, R⁸, and R⁹ taken together represent a part of a ring structure having 3 to 20 ring atoms together with the carbon atom to which the two or more of R⁷, R⁸, and R⁹ bond; and A⁺ represents a monovalent radiation-sensitive onium cation.

### DESCRIPTION OF EMBODIMENTS

According to an embodiment of the invention, a radiation-sensitive resin composition contains:

a polymer (may be also known as “(A) polymer” or “polymer (A)”) having:
a first structural unit including a phenolic hydroxyl group;
a second structural unit including a group represented by the following formula (1); and
   a third structural unit including an acid-labile group;

a radiation-sensitive acid generator (may be also known as “(B) acid generator” or “acid generator (B)”; and

a compound (may be also known as “(C) compound” or “compound (C)”) represented by the following formula (2),

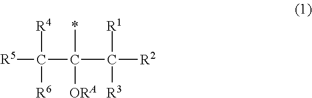

wherein, in the above formula (1),

R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, wherein at least one of R¹, R², R³, R⁴, R⁵, and R⁶ represents a fluorine atom or a fluorinated hydrocarbon group;

R^{A} represents a hydrogen atom or a monovalent organic group having 1 to 20 carbon atoms; and

* denotes a binding site to a part other than the group represented by the above formula (1) in the second structural unit, and

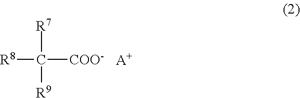

in the above formula (2),

R⁷, R⁸, and R⁹ each independently represent a hydrogen atom, a fluorine atom, or a monovalent organic group having 1 to 40 carbon atoms, or two or more of R⁷, R⁸, and R⁹ taken together represent a part of a ring structure having 3 to 20 ring atoms constituted together with the carbon atom to which the two or more of R⁷, R⁸, and R⁹ bond; and

A⁺ represents a monovalent radiation-sensitive onium cation.

According to another embodiment of the invention, a resist pattern-forming method includes: applying the radiation-sensitive resin composition of the embodiment of the invention directly or indirectly on a substrate; exposing a resist film formed in the applying; and developing the resist film exposed.

The radiation-sensitive resin composition and the resist pattern-forming method of the embodiments of the present invention enable formation of a resist pattern with favorable sensitivity to exposure light, superiority with regard to LWR performance, and a broad process window. Therefore, these can be suitably used in manufacturing processes of semiconductor devices and the like, in which further progress of miniaturization is expected in the future. Hereinafter, the embodiments of the present invention will be explained in detail.

### Radiation-Sensitive Resin Composition

The radiation-sensitive resin composition according to an embodiment of the present invention contains the polymer (A), the acid generator (B), and the compound (C). The radiation-sensitive resin composition may contain, as a favorable component, a solvent (may be also known as “(D) organic solvent” or “organic solvent (D)”), and may also contain, within a range not leading to impairment of the effects of the present invention, other optional component(s).

Due to the polymer (A), the acid generator (B), and the compound (C) being contained, the radiation-sensitive resin composition enables a resist pattern to be formed with favorable sensitivity to exposure light, superiority with regard to LWR performance, and a broad process window. Although not necessarily clarified and without wishing to be bound by any theory, the reason for achieving the aforementioned effects by the radiation-sensitive resin composition due to involving such a constitution may be presumed, for example, as in the following. When the polymer (A) contained in the radiation-sensitive resin composition has the first structural unit including the phenolic hydroxyl group; and the second structural unit including the group represented by the above formula (1), solubility in a developer solution improves. Furthermore, when the radiation-sensitive resin composition contains the compound (C), solubility in a developer solution further improves. It is presumed that as a result, the radiation-sensitive resin composition enables formation of a resist pattern with favorable sensitivity to exposure light, superiority with regard to LWR performance, and a broad process window.

Each component contained in the radiation-sensitive resin composition will be described below.

(A) Polymer

The polymer (A) has: a first structural unit (hereinafter, may be also referred to as simply “first structural unit”) including a phenolic hydroxyl group; a second structural unit (hereinafter, may be also referred to as simply “second structural unit”) including a group represented by formula (1); and a third structural unit (hereinafter, may be also referred to as simply “third structural unit”) including an acid-labile group. The polymer (A) may also have other structural unit(s) aside from the first structural unit, the second structural unit, and the third structural unit. The polymer (A) may contain one, or two or more types of each structural unit.

Each structural unit in the polymer (A) will be described below.

First Structural Unit

The first structural unit includes a phenolic hydroxyl group. “Phenolic hydroxyl group” as referred to herein is not limited to a hydroxy group directly linked to a benzene ring, and means any hydroxy group directly linked to an aromatic ring in general. When the polymer (A) has the first structural unit, hydrophilicity of the resist film can be increased, solubility in a developer solution can be appropriately adjusted, and further, adhesiveness of the resist pattern to the substrate can be improved. Furthermore, in a case of using an extreme ultraviolet ray or an electron beam as the radioactive ray for irradiation in a step of exposing of the resist pattern-forming method, as described later, the sensitivity to exposure light can be further improved.

The first structural unit is exemplified by structural units represented by the following formula (3), and the like.

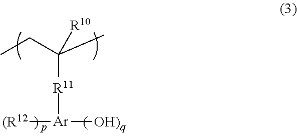

In the above formula (3),

R¹⁰ represents a hydrogen atom, a fluorine atom, a methyl group, or a trifluoromethyl group;

R¹¹ represents a single bond, —O—, —COO—, or —CONH—;

Ar represents a group obtained by removing (p+q+1) hydrogen atoms from an aromatic ring of an arene having 6 to 20 ring atoms;

p is an integer of 0 to 10, wherein in a case in which p is 1, R¹² represents a halogen atom or a monovalent organic group having 1 to 20 carbon atoms, and in a case in which p is no less than 2, a plurality of R¹²s are identical or different from each other, and each R¹² represents a halogen atom or a monovalent organic group having 1 to 20 carbon atoms, or two or more of the plurality of R¹²s taken together represent a part of a ring structure having 4 to 20 ring atoms constituted together with the carbon chain to which the two or more of the plurality of R¹²s bond; and

q is an integer of 1 to 11, wherein

a sum of p and q is no greater than 11.

In light of a degree of copolymerization of a monomer that gives the first structural unit, R¹⁰ represents preferably a hydrogen atom or a methyl group.

In the case in which R¹¹ is —COO—, an oxy-oxygen atom is preferably bonded to Ar, and in the case in which R¹¹ is —CONH—, a nitrogen atom is preferably bonded to Ar. More specifically, given that ** denotes a binding site with Ar, —COO— is preferably —COO—**, and —CONH— is preferably —CONH—**. R¹¹ represents preferably a single bond or —COO—, and more preferably a single bond.

The number of “ring atoms” as referred to herein means the number of atoms constituting the ring in an alicyclic structure, an aromatic carbocyclic structure, an aliphatic heterocyclic structure, or an aromatic heterocyclic structure, and in the case of a polycyclic ring structure, the number of “ring atoms” means the number of atoms constituting the polycyclic ring.

Examples of the arene having 6 to 20 ring atoms that gives Ar include benzene, naphthalene, anthracene, phenanthrene, tetracene, pyrene, and the like. Ar is preferably benzene or naphthalene, and more preferably benzene.

The “organic group” as referred to herein means a group that has at least one carbon atom. The number of “carbon atoms” as referred to herein means the number of carbon atoms constituting a group. The monovalent organic group having 1 to 20 carbon atoms which may be represented by R¹² is exemplified by: a monovalent hydrocarbon group having 1 to 20 carbon atoms; a group (α) that contains a divalent hetero atom-containing group between two adjacent carbon atoms of the hydrocarbon group; a group (β) obtained by substituting with a monovalent hetero atom-containing group, a part or all of hydrogen atoms included in the monovalent hydrocarbon group or the group that contains a divalent hetero atom-containing group; a group (γ) obtained by combining the monovalent hydrocarbon group, the group (α), or the group (β) with a divalent hetero atom-containing group; and the like.

The “hydrocarbon group” as referred to herein may include a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not containing a cyclic structure but being constituted with only a chain structure, and both a linear hydrocarbon group and a branched hydrocarbon group may be contained. The “alicyclic hydrocarbon group” as referred to herein means a hydrocarbon group that contains, as a ring structure, not an aromatic ring structure but an alicyclic structure alone, and may include both a monocyclic alicyclic hydrocarbon group and a polycyclic alicyclic hydrocarbon group. However, it is not necessary for the alicyclic hydrocarbon group to be constituted with only an alicyclic structure; it may contain a chain structure in a part thereof. The “aromatic hydrocarbon group” as referred to herein means a hydrocarbon group that contains an aromatic ring structure as a ring structure. However, it is not necessary for the aromatic hydrocarbon group to be constituted with only an aromatic ring structure; it may contain a chain structure or an alicyclic structure in a part thereof.

The monovalent hydrocarbon group containing 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, and an i-propyl group; alkenyl groups such as an ethenyl group, a propenyl group, and a butenyl group; alkynyl groups such as an ethynyl group, a propynyl group, and a butynyl group; and the like.

Examples of the monovalent alicylic hydrocarbon group having 3 to 20 carbon atoms include: alicyclic saturated hydrocarbon groups such as a cyclopentyl group, a cyclohexyl group, a norbornyl group, an adamantyl group, a tricyclodecyl group, and a tetracyclododecyl group; alicyclic unsaturated hydrocarbon groups such as a cyclopentenyl group, a cyclohexenyl group, a nobornenyl group, a tricyclodecenyl group, and a tetracyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a napthylmethyl group, and an anthrylmethyl group; and the like.

The hetero atom constituting the monovalent hetero atom-containing group or the divalent hetero atom-containing group is exemplified by an oxygen atom, a nitrogen atom, a sulfur atom, a phosphorus atom, a silicon atom, and a halogen atom. Examples of the halogen atom include a fluorine atom, a chlorine atom, a bromine atom, an iodine atom, and the like.

Examples of the divalent hetero atom-containing group include —O—, —CO—, —S—, —CS—, —NR′—, a combination of two or more of these, and the like. R′ represents a hydrogen atom or a monovalent hydrocarbon group.

R¹² represents preferably the monovalent hydrocarbon group, and more preferably the alkyl group.

Examples of the ring structure having 4 to 20 ring atoms constituted by the two or more of the plurality of R¹²s taken together with the carbon atom to which the two or more of the plurality of R¹²s bond include alicyclic structures such as a cyclopentane structure, a cyclohexane structure, a cyclopentene structure, a cyclohexene structure, and the like.

p is preferably 0 to 2, more preferably 0 or 1, and still more preferably 0.

q is preferably 1 to 3, and more preferably 1 or 2.

The first structural unit is exemplified by structural units represented by the following formulae (3-1) to (3-12), and the like.

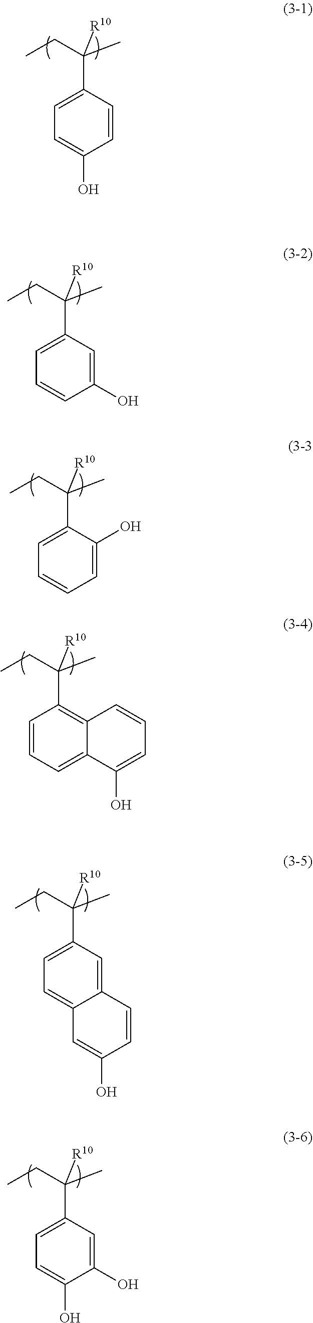

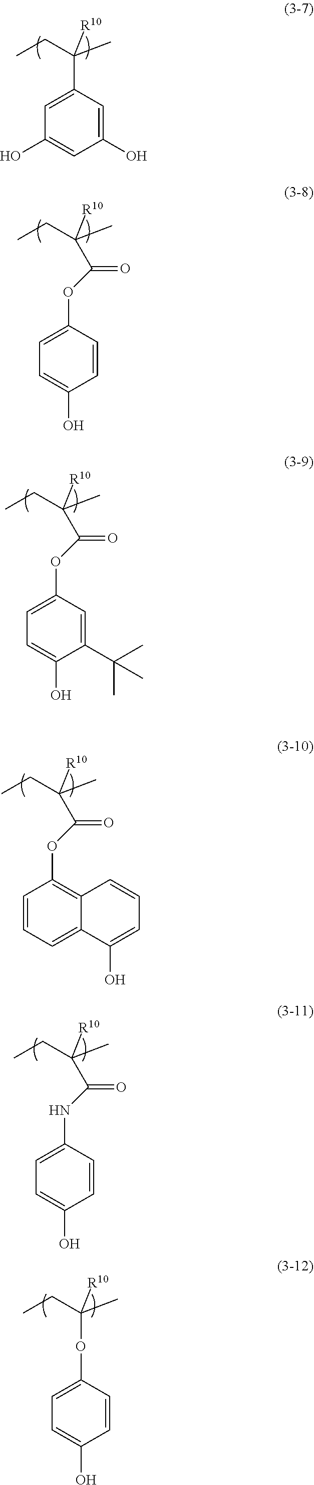

In the above formulae (3-1) to (3-12), R¹⁰ is as defined in the above formula (3).

The first structural unit is preferably represented by the above formula (3-1) or the above formula (3-2).

The lower limit of a proportion of the first structural unit in the polymer (A) contained with respect to total structural units constituting the polymer (A) is preferably 10 mol %, more preferably 15 mol %, still more preferably 20 mol %, and particularly preferably mol %. The upper limit of the proportion is preferably 70 mol %, more preferably 65 mol %, still more preferably 60 mol %, and particularly preferably 55 mol %. When the proportion of the first structural unit falls within the above range, with regard to the resist pattern formed by the radiation-sensitive resin composition, the sensitivity to exposure light and the LWR performance can be further improved, and the process window can be further expanded.

Second Structural Unit

The second structural unit includes a group represented by the following formula (1).

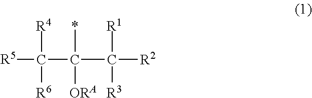

In the above formula (1),

R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, wherein at least one of R¹, R², R³, R⁴, R⁵, and R⁶ represents a fluorine atom or a fluorinated hydrocarbon group;

R^{A} represents a hydrogen atom or a monovalent organic group having 1 to 20 carbon atoms; and

* denotes a binding site to a part other than the group represented by the above formula (1) in the second structural unit.

The hydrocarbon group which may be substituted by a fluorine atom included in the monovalent fluorinated hydrocarbon group having 1 to 10 carbon atoms which may be represented by each of R¹, R², R³, R⁴, R⁵, and R⁶ is exemplified by groups similar to the hydrocarbon groups exemplified as R¹² in the above formula (3), and the like. Specifically, examples of the monovalent fluorinated hydrocarbon group having 1 to 10 carbon atoms include a fluorinated alkyl group having 1 to 10 carbon atoms, and the like.

Examples of the monovalent organic group having 1 to 20 carbon atoms which may be represented by R^{A} include groups similar to the monovalent organic groups exemplified as R¹² in the above formula (3), and the like.

R¹, R², R³, R⁴, R⁵, and R⁶ each represent preferably a fluorine atom or the monovalent fluorinated hydrocarbon group having 1 to 10 carbon atoms, more preferably a fluorine atom or a monovalent fluorinated alkyl group having 1 to 10 carbon atoms, and still more preferably a fluorine atom.

At least one of R¹, R², R³, R⁴, R⁵, and R⁶ represents a fluorine atom or the fluorinated hydrocarbon group; it is preferred that at least two of R¹, R², R³, R⁴, R⁵, and R⁶ represent a fluorine atom or the fluorinated hydrocarbon group; it is more preferred that at least two of R¹, R², and R³, and at least two of R⁴, R⁵, and R⁶ represent a fluorine atom or the fluorinated hydrocarbon group; it is still more preferred that R¹, R², R³, R⁴, R⁵, and R⁶ each represent a fluorine atom or the fluorinated hydrocarbon group; and it is particularly preferred that R¹, R², R³, R⁴, R⁵, and R⁶ each represent a fluorine atom.

R^{A} represents preferably a hydrogen atom.

The second structural unit is exemplified by structural units represented by the following formulae (1-1) and (1-2), and the like.

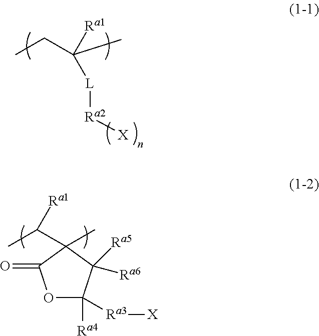

In each of the above formulae (1-1) and (1-2), R^{a1} represents a hydrogen atom, a fluorine atom, a methyl group, or a trifluoromethyl group, and X represents a group represented by the above formula (1).

In the above formula (1-1), L represents a single bond or —COO—; R^{a2} represents a monovalent organic group having a valency of (n+1), and having 1 to 20 carbon atoms; and n is an integer of 1 to 3, wherein in a case in which n is no less than 2, a plurality of Xs are identical or different from each other.

In the above formula (1-2), R^{a3} represents a divalent hydrocarbon group having 1 to carbon atoms; R^{a4} represents a monovalent hydrocarbon group having 1 to 20 carbon atoms; and R^{a5} and R^{a6} each independently represent a hydrogen atom or a monovalent hydrocarbon group having 1 to 10 carbon atoms, or R^{a5} and R^{a6} taken together represent a part of a ring structure having 3 to 20 ring atoms, constituted together with the carbon atom to which R^{a5} and R^{a6} bond.

In light of a degree of copolymerization of a monomer that gives the second structural unit, R^{a1} represents preferably a hydrogen atom or a methyl group.

In the above formula (1-1), L represents preferably —COO—. In the case in which L is —COO—, an oxy-oxygen atom preferably bonds to R^{a2}. More specifically, given that *** denotes a binding site with R^{a2}, —COO— is preferably —COO—***.

Examples of R^{a2} include groups obtained by removing n hydrogen atoms from the monovalent organic groups exemplified as R¹² in the above formula (3), and the like. R^{a2} represents preferably a hydrocarbon group, more preferably a chain hydrocarbon group or an alicyclic hydrocarbon group, still more preferably a saturated chain hydrocarbon group or an alicyclic saturated hydrocarbon group, and particularly preferably an alicyclic saturated hydrocarbon group.

n is preferably 1 or 2, and more preferably 1.

Examples of R^{a3} include groups obtained by removing one hydrogen atom from the monovalent hydrocarbon groups exemplified as R¹² in the above formula (3), and the like. R^{a3} represents preferably a chain hydrocarbon group, and more preferably a saturated chain hydrocarbon group.

Examples of R^{a4} include groups similar to the hydrocarbon groups exemplified as R¹² in the above formula (3), and the like. R^{a4} represents preferably a monovalent aromatic hydrocarbon group having 6 to 20 carbon atoms, and more preferably an aryl group.

Examples of the monovalent hydrocarbon group having 1 to 10 carbon atoms which may be represented by R^{a5} or R^{a6} include groups similar to the hydrocarbon groups exemplified as R¹² in the above formula (3), and the like. R^{a5} and R^{a6} each represent preferably a hydrogen atom.

Examples of the ring structure having 3 to 20 ring atoms constituted together with the carbon atom to which R^{a5} and R^{a6} bond include an alicyclic structure having 3 to 20 ring atoms, and the like.

Among candidates of the second structural unit, the structural unit represented by the above formula (1-1) is exemplified by structural units represented by the following formulae (1-1-1) to (1-1-3), and the like.

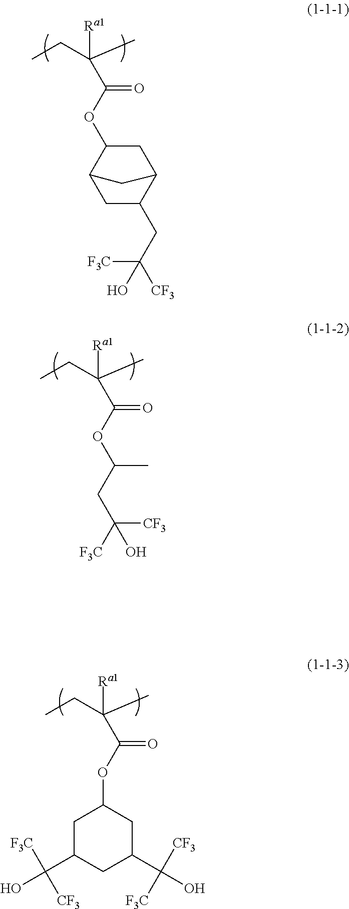

In the above formulae (1-1-1) to (1-1-3), R^{a1} is as defined in the above formula (1-1).

The structural unit represented by the above formula (1-2) among candidates of the second structural unit is exemplified by a structural unit represented by the following formula (1-2-1), and the like.

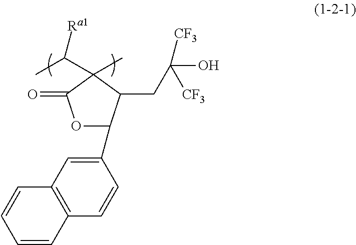

In the above formula (1-2-1), R^{a1} is as defined in the above formula (1-2).

The second structural unit is preferably represented by the above formula (1-1-1) or (1-2-1).

The lower limit of a proportion of the second structural unit in the polymer (A) contained with respect to total structural units constituting the polymer (A) is preferably 3 mol %, more preferably 5 mol %, and still more preferably 10 mol %. The upper limit of the proportion is preferably 50 mol %, more preferably 45 mol %, and still more preferably 40 mol %. When the proportion of the second structural unit falls within the above range, with regard to the resist pattern formed by the radiation-sensitive resin composition, the sensitivity to exposure light and the LWR performance can be further improved, and the process window can be further expanded.

Third Structural Unit

The third structural unit includes an acid-labile group. The “acid-labile group” as referred to herein means a group that substitutes for a hydrogen atom of a carboxy group, a phenolic hydroxyl group, or the like, and is dissociable by an action of an acid. When the polymer (A) includes the acid-labile group in the third structural unit, the acid-labile group is dissociated in light-exposed regions by an action of an acid generated from the acid generator (B) in the exposing, and a difference in solubility in a developer solution emerges between the light-exposed regions and the light-unexposed regions, thereby enabling forming the resist pattern.

The third structural unit is exemplified by structural units represented by the following formulae (4-1A), (4-1B), (4-2A), and (4-2B), and the like. It is to be noted that in each of the following formulae (4-1A) to (4-2B), —CR^{X}R^{Y}R^{Z} or —CR^{U}R^{V}(OR^{W}) bonding to an oxy-oxygen atom derived from the carboxy group or the phenolic hydroxyl group corresponds to the acid-labile group.

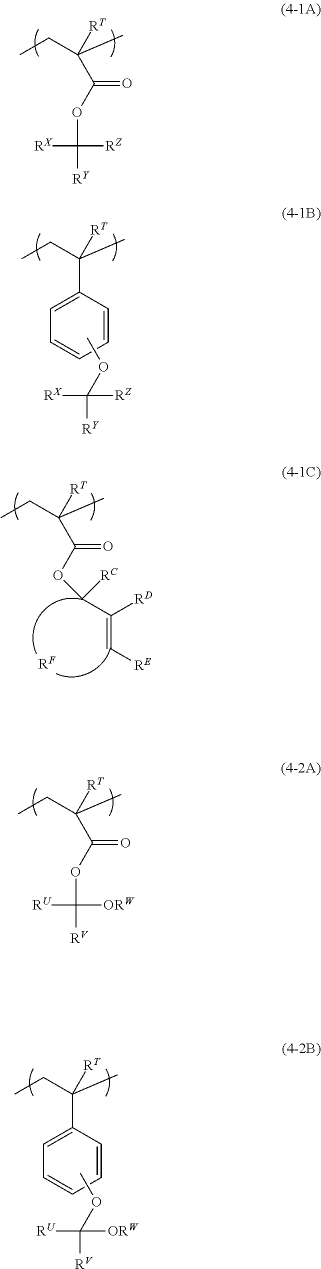

In each of the above formulae (4-1A), (4-1), (4-C), (4-2A), and (4-2B), R^{T} represents a hydrogen atom, a fluorine atom, a methyl group, or a trifluoromethyl group.

In each of the above formulae (4-1A) and (4-1),

R^{X} represents a hydrogen atom or a monovalent hydrocarbon group having 1 to 20 carbon atoms; and

R^{Y} and R^{Z} each independently represent a monovalent hydrocarbon group having 1 to 20 carbon atoms, or R^{Y} and R^{Z} taken together represent a part of an alicyclic structure having 3 to 20 ring atoms constituted together with the carbon atom to which R^{Y} and R^{Z} bond.

In the above formula (4-1C),

R^{C} represents a hydrogen atom;

R^{D} and R^{E} each independently represent a hydrogen atom or a monovalent hydrocarbon group having 1 to 20 carbon atoms; and

R^{F} represents a divalent hydrocarbon group having 1 to 20 carbon atoms constituting an unsaturated alicyclic structure having 4 to 20 ring atoms together with the carbon atom to which each of R^{C}, R^{D}, and R^{E} bonds.

In each of the above formulae (4-2A) and (4-2B),

R^{U} and R^{V} each independently represent a hydrogen atom or a monovalent hydrocarbon group having 1 to 20 carbon atoms, and R^{W} represents a monovalent hydrocarbon group having 1 to 20 carbon atoms, or

R^{U} and R^{V} taken together represent a part of an alicyclic structure having 3 to 20 ring atoms constituted together with the carbon atom to which R^{U} and R^{V} bond, or R^{U} and R^{W} taken together represent a part of an aliphatic heterocyclic structure having 5 to 20 ring atoms constituted together with the carbon atom to which R^{U} bonds and the oxygen atom to which R^{W} bonds.

In light of a degree of copolymerization of a monomer that gives the third structural unit, R^{T} represents preferably a hydrogen atom or a methyl group.

Examples of the monovalent hydrocarbon group having 1 to 20 carbon atoms which may be represented by R^{X}, R^{Y}, R^{Z}, R^{D}, R^{E}, R^{U}, R^{V}, or R^{W} include groups similar to the hydrocarbon groups exemplified as R¹² in the above formula (3), and the like.

Examples of the divalent hydrocarbon group having 1 to 20 carbon atoms which may be represented by R^{F} include a group obtained by removing one hydrogen atom from the monovalent hydrocarbon group exemplified as R¹² in the above formula (3), and the like.

Examples of the alicyclic structure having 3 to 20 ring atoms which may be represented by R^{Y} and R^{Z} taken together or R^{U} and R^{V} taken together, constituted together with the carbon atom to which R^{Y} and R^{Z} or R^{U} and R^{V} bond include:

monocyclic saturated alicyclic structures such as a cyclopropane structure, a cyclobutane structure, a cyclopentane structure, and a cyclohexane structure;

polycyclic saturated alicyclic structures such as a norbornane structure, an adamantane structure, a tricyclodecane structure, and a tetracyclododecane structure;

monocyclic unsaturated alicyclic structures such as a cyclopropene structure, a cyclobutene structure, a cyclopentene structure, and a cyclohexene structure;

polycyclic unsaturated alicyclic structures such as a norbornene structure, a tricyclodecene structure, and a tetracyclododecene structure; and the like.

Examples of the aliphatic heterocyclic structure having 5 to 20 ring atoms which may be represented by R^{U} and R^{W} taken together, constituted together with the carbon atom to which R^{U} bonds and the oxygen atom to which R^{W} bonds include:

saturated oxygen-containing heterocyclic structures such as an oxacyclobutane structure, an oxacyclopentane structure, and an oxacyclohexane structure;

unsaturated oxygen-containing heterocyclic structures such as an oxacyclobutene structure, an oxacyclopentene structure, and an oxacyclohexene structure; and the like.

Examples of the unsaturated alicyclic ring structure having 4 to 20 ring atoms constituted from R^{F} together with the carbon atom to which each of R^{C}, R^{D}, and R^{E} bonds include unsaturated alicyclic structures such as a cyclobutene structure, a cyclopentene structure, a cyclohexene structure, and a norbornene structure; and the like.

In each of the above formulae (4-1A) and (4-1), R^{X} represents preferably a hydrocarbon group, more preferably a chain hydrocarbon group or an aromatic hydrocarbon group, and still more preferably an alkyl group or an aryl group.

In each of the above formulae (4-1A) and (4-1), R^{Y} and R^{Z} each represent preferably a hydrocarbon group, more preferably a chain hydrocarbon group or an alicyclic hydrocarbon group, and still more preferably an alkyl group or an alicyclic saturated hydrocarbon group.

In each of the above formulae (4-2A) and (4-2B), R^{U} represents preferably a hydrogen atom or a hydrocarbon group, and more preferably a hydrogen atom.

In each of the above formulae (4-2A) and (4-2B), R^{V} and R^{W} each represent preferably a hydrocarbon group, and more preferably a chain hydrocarbon group.

The third structural unit is preferably represented by the above formula (4-A).

The lower limit of a proportion of the third structural unit in the polymer (A) contained with respect to total structural units constituting the polymer (A) is preferably 5 mol %, more preferably 10 mol %, and still more preferably 15 mol %. The upper limit of the proportion is preferably 80 mol %, more preferably 70 mol %, and still more preferably 60 mol %. When the proportion of the third structural unit falls within the above range, with regard to the resist pattern formed by the radiation-sensitive resin composition, the sensitivity to exposure light and the LWR performance can be further improved, and the process window can be further expanded.

Other Structural Unit(s)

Other structural unit(s) is/are exemplified by a structural unit containing a lactone structure, a cyclic carbonate structure, a sultone structure, or a combination thereof, a structural unit including an alcoholic hydroxyl group and being other than the second structural unit; a structural unit derived from benzyl (meth)acrylate; and the like. When the polymer (A) further includes this/these other structural unit(s), solubility in a developer solution can be further appropriately adjusted, and as a result, with regard to the resist pattern formed by the radiation-sensitive resin composition, the sensitivity to exposure light and the LWR performance can be still further improved, and the process window can be still further expanded. Furthermore, adhesiveness of the resist pattern to the substrate can be still further improved.

Examples of the structural unit containing a lactone structure, a cyclic carbonate structure, a sultone structure, or a combination thereof include structural units represented by the following formulae, and the like.

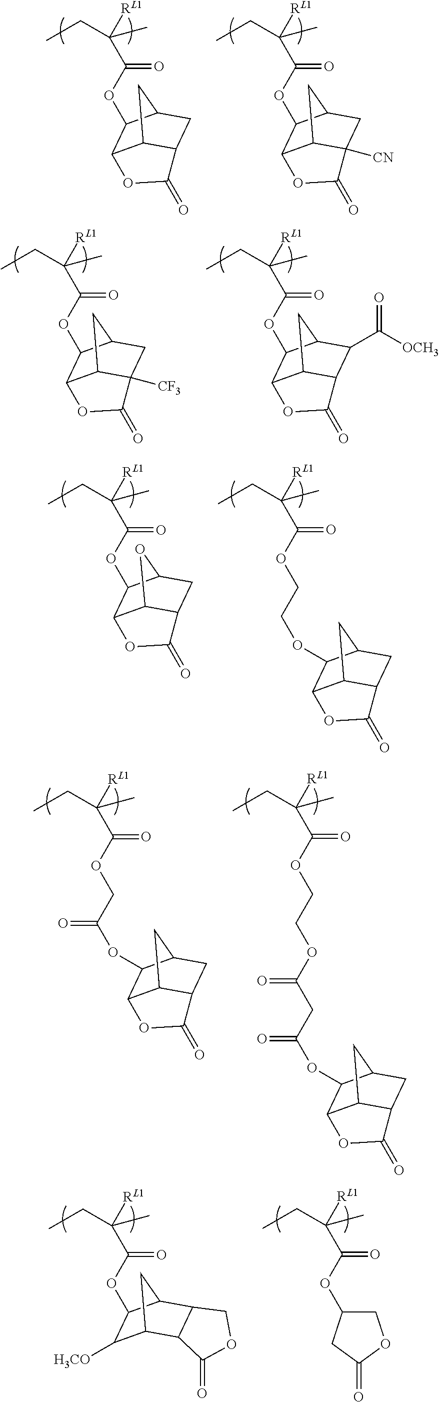

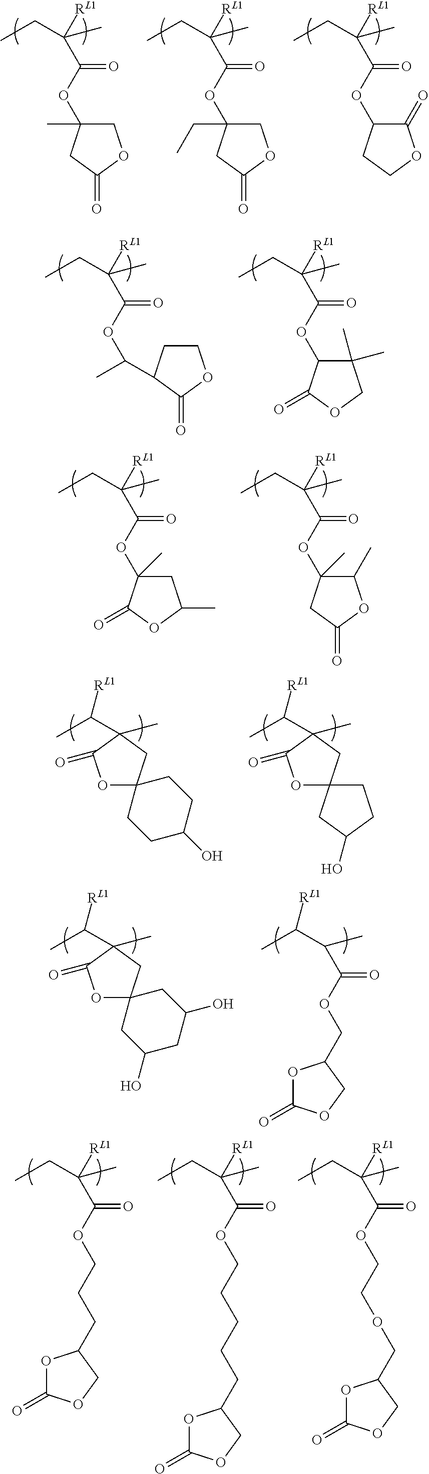

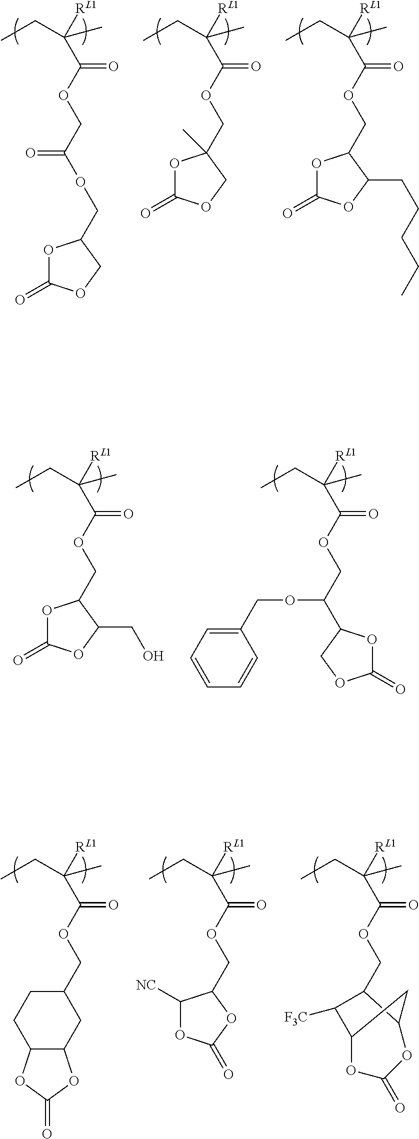

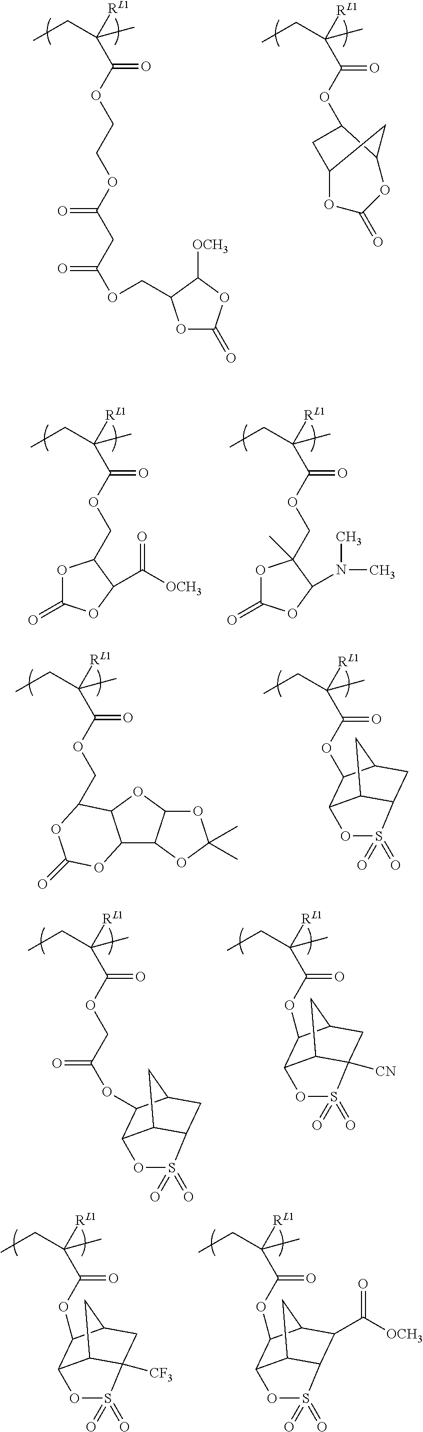

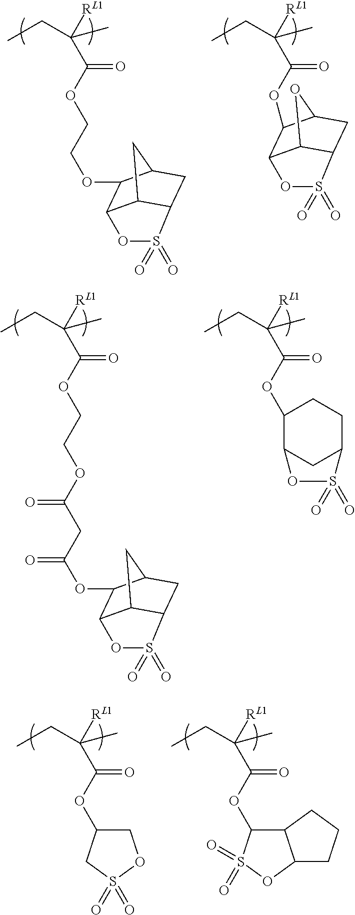

In each of the above formulae, R^{L1} represents a hydrogen atom, a fluorine atom, a methyl group, or a trifluoromethyl group.

The structural unit containing a lactone structure, a cyclic carbonate structure, a sultone structure, or a combination thereof is preferably a structural unit containing a lactone structure, more preferably a structural unit containing a nobornane lactone structure, and still more preferably a structural unit derived from norbornane lactone-yl (meth)acrylate.

Examples of the structural unit including an alcoholic hydroxyl group and being other than the second structural unit include structural units represented by the following formulae, and the like.

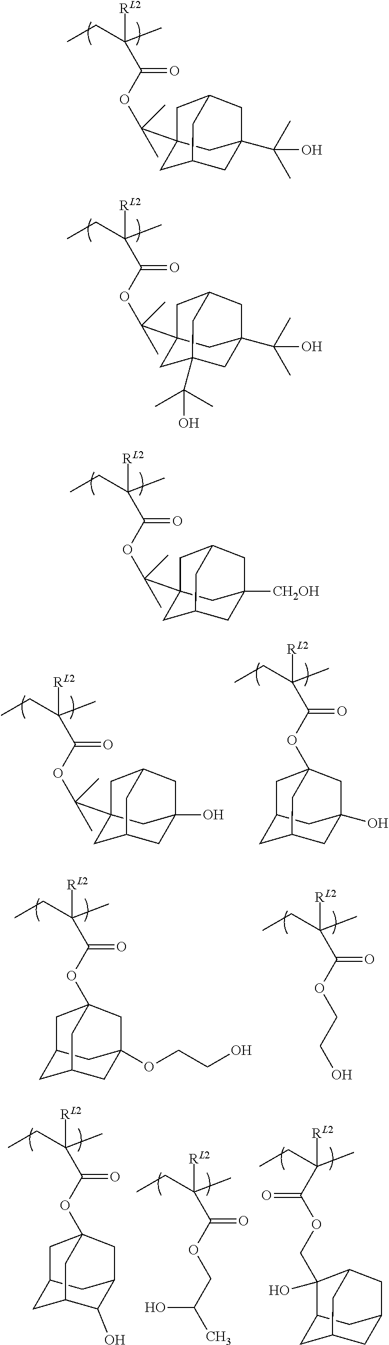

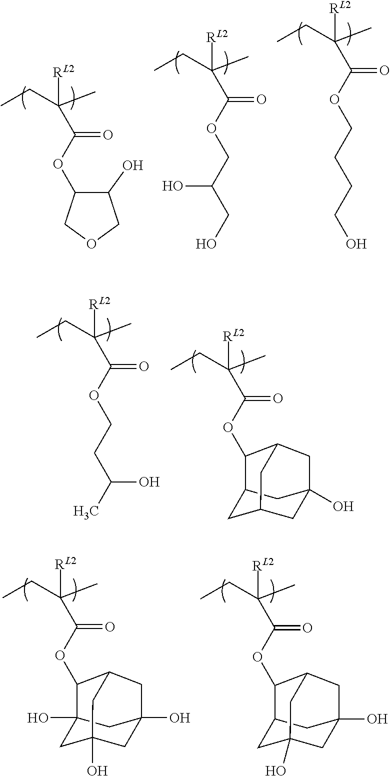

In each of the above formulae, R^{L2} represents a hydrogen atom, a fluorine atom, a methyl group, or a trifluoromethyl group.

In the case in which the polymer (A) has the other structural unit(s), the lower limit of a proportion of the other structural unit(s) contained with respect to total structural units in the polymer (A) is preferably 1 mol %, and more preferably 5 mol %. The upper limit of the proportion is preferably 30 mol %, and more preferably 20 mol %.

The lower limit of a polystyrene-equivalent weight average molecular weight of the polymer (A) as determined by gel permeation chromatography (GPC) is preferably 2,000, more preferably 3,000, still more preferably 4,000, and particularly preferably 5,000. The upper limit of the Mw is preferably 11,000, more preferably 10,000, still more preferably 9,000, and particularly preferably 8,000. When the Mw of the polymer (A) falls within the above range, coating characteristics of the radiation-sensitive resin composition can be improved, and as a result, with regard to the resist pattern formed by the radiation-sensitive resin composition, the sensitivity to exposure light and the LWR performance can be further improved, and the process window can be further expanded.

The upper limit of a ratio (Mw/Mn) of a polystyrene-equivalent number average molecular weight (Mn) of the polymer (A) as determined by GPC with respect to the Mw is preferably 2.50, more preferably 2.00, and still more preferably 1.75. The lower limit of the ratio is typically 1.00, preferably 1.10, and more preferably 1.20. When the Mw/Mn of the polymer (A) falls within the above range, the coating characteristics of the radiation-sensitive resin composition can be further improved.

The Mw and Mn of the polymer herein are values determined by gel permeation chromatography (GPC) under the following conditions.

GPC columns: “G2000 HXL”×2, “G3000 HXL”×1, and “G4000 HXL”×1, available from Tosoh Corporation;

elution solvent: tetrahydrofuran;

flow rate: 1.0 mL/min;

sample concentration: 1.0% by mass;

amount of injected sample: 100 μL;

column temperature: 40° C.;

detector: differential refractometer; and

standard substance: mono-dispersed polystyrene

The lower limit of a proportion of the polymer (A) in the radiation-sensitive resin composition with respect to all components other than the organic solvent (D) is preferably 50% by mass, more preferably 60% by mass, still more preferably 70% by mass, and particularly preferably 80% by mass.

The polymer (A) can be synthesized by, for example, polymerizing a monomer that gives each structural unit according to a well-known procedure.

### (B) Acid Generator

The acid generator (B) is a substance which generates an acid by irradiation with a radioactive ray. Examples of the radioactive ray include electromagnetic waves such as visible light rays, ultraviolet rays, far ultraviolet rays, extreme ultraviolet rays (EUV), X-rays, and γ-rays; charged particle rays such as electron beams and α-rays; and the like. The acid-labile group included in the third structural unit of the polymer (A) is disassociated by an action of an acid generated from the acid generator (B) in irradiation (exposure) with a radioactive ray, generating a carboxy group and creating a difference in solubility in the developer solution of the polymer (A) between a light-exposed region and a light-unexposed region; accordingly, a resist pattern can be formed. The form in which the acid generator (B) is contained in the radiation-sensitive resin composition is exemplified by a low-molecular-weight compound (hereinafter, may be also referred to as “(B) acid generating agent” or “acid generating agent (B)”), an acid generator incorporated as a part of the polymer (A), and a combination of both these forms.

The lower limit of a temperature at which the acid disassociates the acid-labile group is preferably 80° C., more preferably 90° C., and still more preferably 100° C. The upper limit of the temperature is preferably 130° C., more preferably 120° C., and still more preferably 110° C. The lower limit of a time period for the acid to disassociate the acid-labile group is preferably 10 sec, and more preferably 1 min. The upper limit of the time period is preferably 10 min, and more preferably 2 min.

Examples of the acid generated from the acid generator (B) include sulfonic acid, imidic acid, and the like.

The acid generating agent (B) is exemplified by an onium salt compound, an N-sulfonyloxyimide compound, a sulfonimide compound, a halogen-containing compound, a diazoketone compound, and the like.

Examples of the onium salt compound include sulfonium salts, tetrahydrothiophenium salts, iodonium salts, phosphonium salts, diazonium salts, pyridinium salts, and the like.

Specific examples of the acid generating agent (B) include compounds disclosed in paragraphs [0080] to [0113] of Japanese Unexamined Patent Application, Publication No. 2009-134088, and the like.

The acid generating agent (B) that generates sulfonic acid by irradiation with a radioactive ray is exemplified by a compound (hereinafter, may be also referred to as “compound (5)”) represented by the following formula (5), and the like. It is considered that when the acid generating agent (B) has the following structure, a diffusion length of the acid generated in the resist film is more appropriately shortened by an interaction with the polymer (A) and the like, and as a result, with regard to the resist pattern formed by the radiation-sensitive resin composition, the sensitivity to exposure light and the LWR performance can be further improved, and the process window can be further expanded.

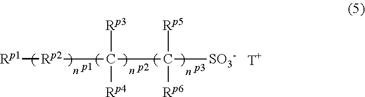

In the above formula (5),

R^{P1} represents a monovalent group containing a ring structure having 5 or more ring atoms;

R^{P2} represents a divalent linking group;

R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms;

R^{p5} and R^{p6} each independently represent a fluorine atom or a monovalent fluorinated hydrocarbon group having 1 to 20 carbon atoms;

n^{p1} is an integer of 0 to 10, n^{p2} is an integer of 0 to 10, and n^{p3} is an integer of 0 to 10, wherein
a sum of n^{p1}, n^{p2}, and n^{p3} is no less than 1 and no greater than 30,
in a case in which n^{p1} is no less than 2, a plurality of R^{p2}s are identical or different from each other,
in a case in which n^{p2} is no less than 2, a plurality of R^{p3}s are identical or different from each other, and a plurality of R^{p4}s are identical or different from each other, and
in a case in which n^{p3} is no less than 2, a plurality of R^{p5}s are identical or different from each other, and a plurality of R^{p6}s are identical or different from each other; and

T⁺ represents a monovalent radiation-sensitive onium cation.

The monovalent group containing a ring structure having 5 or more ring atoms which may be represented by R^{p1} is exemplified by a monovalent group containing an alicyclic structure having 5 or more ring atoms, a monovalent group containing an aliphatic heterocyclic structure having 5 or more ring atoms, a monovalent group containing an aromatic carbocyclic structure having 5 or more ring atoms, a monovalent group containing an aromatic heterocyclic structure having 5 or more ring atoms, and the like.

Examples of the alicyclic structure having 5 or more ring atoms include:

monocyclic saturated alicyclic structures such as a cyclopentane structure, a cyclohexane structure, a cycloheptane structure, a cyclooctane structure, a cyclononane structure, a cyclodecane structure, and a cyclododecane structure;

monocyclic unsaturated alicyclic structures such as a cyclopentene structure, a cyclohexene structure, a cycloheptene structure, a cyclooctene structure, and a cyclodecene structure;

polycyclic saturated alicyclic structures such as a norbornane structure, an adamantane structure, a tricyclodecane structure, and a tetracyclododecane structure; polycyclic unsaturated alicyclic structures such as a norbornene structure and a tricyclodecene structure; and the like.

Examples of the aliphatic heterocyclic structure having 5 or more ring atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic carbocyclic structure having 5 or more ring atoms include a benzene structure, a naphthalene structure, a phenanthrene structure, an anthracene structure, and the like.

Examples of the aromatic heterocyclic structure having 5 or more ring atoms include:

oxygen atom-containing heterocyclic structures such as a furan structure, a pyran structure, a benzofuran structure, and a benzopyran structure;

nitrogen atom-containing heterocyclic structures such as a pyridine structure, a pyrimidine structure, and an indole structure; and the like.

In the above formula (5), the lower limit of a number of ring atoms in the ring structure of R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the diffusion length of the acid can be more appropriately shortened, and as a result, with regard to the resist pattern formed by the radiation-sensitive resin composition, the sensitivity to exposure light and the LWR performance can be further improved, and the process window can be further expanded.

A part or all of hydrogen atoms in the ring structure of R^{p1} may be substituted with a substituent. Examples of the substituent include: halogen atoms such as a fluorine atom, a chlorine atom, a bromine atom, and an iodine atom; a hydroxy group; a carboxy group; a cyano group; a nitro group; an alkoxy group; an alkoxycarbonyl group; an alkoxycarbonyloxy group; an acyl group; an acyloxy group; and the like. Of these, a hydroxy group is preferred.

R^{p1} represents preferably the monovalent group containing an alicyclic structure having 5 or more ring atoms, or the monovalent group containing an aliphatic heterocyclic structure having 5 or more ring atoms; more preferably a monovalent group containing one of the polycyclic saturated alicyclic structures, a monovalent group containing one of the oxygen atom-containing heterocyclic structures, or a monovalent group containing one of the nitrogen atom-containing heterocyclic structures, wherein each cyclic structure is as exemplified above with respect to the ring structure having 5 or more ring atoms which may be represented by R^{p1}; and still more preferably an adamantyl group, a norbonanesultone-yl group, or an azacyclohexan-yl group.

Examples of the divalent linking group which may be represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group, or a divalent alicyclic saturated hydrocarbon group is preferred, and the carbonyloxy group or the sulfonyl group is more preferred.

Examples of the monovalent hydrocarbon group having 1 to 20 carbon atoms which may be represented by R^{p3} or R^{p4} include an alkyl group having 1 to 20 carbon atoms, and the like. Examples of the monovalent fluorinated hydrocarbon group having 1 to 20 carbon atoms which may be represented by R^{p3} or R^{p4} include a fluorinated alkyl group having 1 to carbon atoms, and the like. R^{p3} and R^{p4} each represent preferably a hydrogen atom, a fluorine atom, or a fluorinated alkyl group, more preferably a fluorine atom or a perfluoroalkyl group, and still more preferably a fluorine atom or a trifluoromethyl group.

Examples of the monovalent fluorinated hydrocarbon group having 1 to 20 carbon atoms which may be represented by R^{p5} or R^{p6} include a fluorinated alkyl group having 1 to carbon atoms, and the like. R^{p5} and R^{p6} each represent preferably a fluorine atom or the fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 2, and still more preferably 0 or 1.

n^{p2} is preferably 0 to 5, more preferably 0 to 2, and still more preferably 0 or 1.

The lower limit of n^{p3} is preferably 1, and more preferably 2. When n^{p3} is no less than 1, strength of the acid generated from the compound (5) can be increased, and as a result, with regard to the resist pattern formed by the radiation-sensitive resin composition, the sensitivity to exposure light and the LWR performance can be further improved, and the process window can be further expanded. The upper limit of n^{p3} is preferably 4, more preferably 3, and still more preferably 2.

The lower limit of the sum of n^{p1}, n^{p2}, and n^{p3} is preferably 2, and more preferably 4. The upper limit of the sum of n^{p1}, n^{p2}, and n^{p3} is preferably 20, and more preferably 10.

The monovalent radiation-sensitive onium cation which may be represented by T⁺ is exemplified by a cation represented by the following formula (r-a) (hereinafter, may be also referred to as “cation (r-a)”), a cation represented by the following formula (r-b) (hereinafter, may be also referred to as “cation (r-b)”), a cation represented by the following formula (r-c) (hereinafter, may be also referred to as “cation r-c”), and the like.

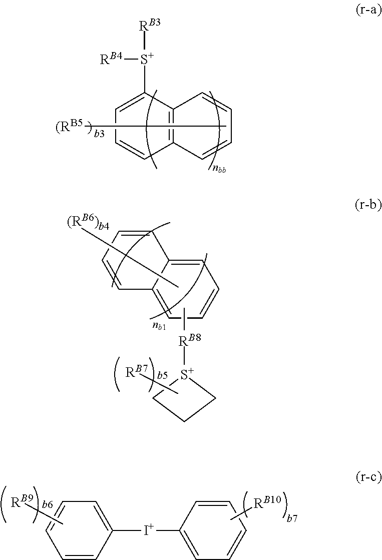

In the above formula (r-a), R^{B3} and R^{B4} each independently represent a monovalent organic group having 1 to 20 carbon atoms; b3 is an integer of 0 to 11, wherein in a case in which b3 is 1, R^{B5} represents a hydroxyl group, a nitro group, a halogen atom, or a monovalent organic group having 1 to 20 carbon atoms, and in a case in which b3 is no less than 2, a plurality of R^{B5}s are identical or different from each other, and each R^{B5} represents a hydroxyl group, a nitro group, a halogen atom, or a monovalent organic group having 1 to 20 carbon atoms, or the plurality of R^{B5}s taken together represent a part of a ring structure having 4 to 20 ring atoms constituted together with the carbon chain to which the plurality of R^{B5}s bond; and n_{bb} is an integer of 0 to 3.

Examples of the monovalent organic group having 1 to 20 carbon atoms which may be represented by R^{B3}, R^{B4}, or R^{B5} include groups similar to the organic groups exemplified as R¹² in the above formula (3), and the like.

R^{B3} and R^{B4} each represent preferably a monovalent unsubstituted hydrocarbon group having 1 to 20 carbon atoms or a hydrocarbon group obtained therefrom by substituting a hydrogen atom included therein with a substituent, more preferably a monovalent unsubstituted aromatic hydrocarbon group having 6 to 18 carbon atoms or an aromatic hydrocarbon group obtained therefrom by substituting a hydrogen atom included therein with a substituent, still more preferably a substituted or unsubstituted phenyl group, and particularly preferably an unsubstituted phenyl group.

The substituent which may substitute for the hydrogen atom included in the monovalent hydrocarbon group having 1 to 20 carbon atoms which may be represented by R^{B3} or R^{B4} is preferably: a substituted or unsubstituted monovalent hydrocarbon group having 1 to 20 carbon atoms; —OSO₂—R^{k}; —SO₂—R^{k}; —OR^{k}; —COOR^{k}; —O—CO—R^{k}; —O—R^{kk}—COOR^{k}; —R^{kk}—CO—R^{k}; or —SR^{k}, wherein R^{k} represents a monovalent hydrocarbon group having 1 to 10 carbon atoms, and wherein R^{k} represents a single bond or a divalent hydrocarbon group having 1 to 10 carbon atoms.

R^{B5} represents preferably: a substituted or unsubstituted monovalent hydrocarbon group having 1 to 20 carbon atoms; —OSO₂—R^{k}; —SO₂—R^{k}; —OR^{k}; —COOR^{k}; —O—CO—R^{k}; —O—R^{kk}—COOR^{k}; —R^{k}—CO—R^{k}; or —SR^{k}, wherein R^{k} represents a monovalent hydrocarbon group having 1 to 10 carbon atoms; and wherein R^{k} represents a single bond or a divalent hydrocarbon group having 1 to 10 carbon atoms.

In the above formula (r-b),

b4 is an integer of 0 to 9; wherein in a case in which b4 is 1, represents a hydroxy group, a nitro group, a halogen atom, or a monovalent organic group having 1 to 20 carbon atoms, and in a case in which b4 is no less than 2, a plurality of R^{B6}s are identical or different from each other, and each R^{B6} represents a hydroxy group, a nitro group, a halogen atom, or a monovalent organic group having 1 to 20 carbon atoms, or the plurality of R^{B6}s taken together represent a part of a ring structure having 4 to 20 ring atoms constituted together with the carbon chain to which the plurality of R^{B6}s bond;

b5 is an integer of 0 to 10, wherein in a case in which b5 is 1, R^{B7} represents a hydroxy group, a nitro group, a halogen atom, or a monovalent organic group having 1 to 20 carbon atoms, and in a case in which b5 is no less than 2, a plurality of R^{B7}s are identical or different from each other, and each R^{B7} represents a hydroxy group, a nitro group, a halogen atom, or a monovalent organic group having 1 to 20 carbon atoms, or the plurality of R^{B7} taken together represent a part of a ring structure having 3 to 20 ring atoms constituted together with the carbon atom or carbon chain to which the plurality of R^{B7}s bond;

n_{b2} is an integer of 0 to 3;

R^{B8} represents a single bond or a divalent organic group having 1 to 20 carbon atoms; and

n_{b1} is an integer of 0 to 2.

R^{B6} and R^{B7} each represent preferably: a substituted or unsubstituted monovalent hydrocarbon group having 1 to 20 carbon atoms; —OR^{k}; —COOR^{k}; —O—CO—R^{k}; —O—R^{kk}—COOR^{k}; or —R^{kk}—CO—R^{k}, wherein R^{k} represents a monovalent hydrocarbon group having 1 to 10 carbon atoms, and wherein R^{kk} represents a single bond or a divalent hydrocarbon group having 1 to carbon atoms.

In the above formula (r-c),

b6 is an integer of 0 to 5, wherein in a case in which b6 is 1, R^{B9} represents a hydroxy group, a nitro group, a halogen atom, or a monovalent organic group having 1 to 20 carbon atoms, in a case in which b6 is no less than 2, a plurality of R^{B9}s are identical or different from each other, and each R^{B9} represents a hydroxy group, a nitro group, a halogen atom, or a monovalent organic group having 1 to 20 carbon atoms, or the plurality of R^{B9}s taken together represent a part of a ring structure having 4 to 20 ring atoms constituted together with the carbon chain to which the plurality of R^{B9}s bond; and

b7 is an integer of 0 to 5, wherein in a case in which b7 is 1, R^{B10} represents a hydroxy group, a nitro group, a halogen atom, or a monovalent organic group having 1 to 20 carbon atoms, and in a case in which b7 is no less than 2, a plurality of R^{B10}s are identical or different from each other, and each R^{B10} represents a hydroxy group, a nitro group, a halogen atom, or a monovalent organic group having 1 to 20 carbon atoms, or the plurality of R^{B10}s taken together represent a part of a ring structure having 4 to 20 ring atoms constituted together with the carbon chain to which the plurality of R^{B10}s bond.

R^{B9} and R^{B10} each represent preferably: a substituted or unsubstituted monovalent hydrocarbon group having 1 to 20 carbon atoms; —OSO₂—R^{k}; —SO₂—R^{k}; —OR^{k}; —COOR^{k}; —O—CO—R^{k}; —O—R^{kk}—COOR^{k}; —R^{kk}—CO—R^{k}; —S—R^{k}; or a ring structure constituted from at least two of these groups taken together, wherein R^{k} represents a monovalent hydrocarbon group having 1 to 10 carbon atoms, and wherein R^{kk} represents a single bond or a divalent hydrocarbon group having 1 to 10 carbon atoms.

Examples of the monovalent hydrocarbon group having 1 to 20 carbon atoms which may be represented by R^{B5}, R^{B6}, R^{B7}, R^{B9}, or R^{B10} include:

linear alkyl groups such as a methyl group, an ethyl group, an n-propyl group, and an n-butyl group;

branched alkyl groups such as an i-propyl group, an i-butyl group, a sec-butyl group, and a t-butyl group;

aryl groups such as a phenyl group, a tolyl group, a xylyl group, a mesityl group, and a naphthyl group;

aralkyl groups such as a benzyl group and a phenethyl group; and the like.

Examples of the divalent organic group which may be represented by R^{B8} include groups obtained by removing one hydrogen atom from the monovalent organic groups having 1 to 20 carbon atoms exemplified as R^{B3}, R^{B4}, and R^{B5} in the above formula (r-a), and the like.

Examples of the substituent which may substitute for the hydrogen atom included in the hydrocarbon groups which may be represented by R^{B5}, R^{B6}, R^{B7}, R^{B9} and R^{B10} include: halogen atoms such as a fluorine atom, a chlorine atom, a bromine atom, and an iodine atom; a hydroxy group; a carboxy group; a cyano group; a nitro group; an alkoxy group; an alkoxycarbonyl group; an alkoxycarbonyloxy group; an acyl group; an acyloxy group; and the like. Of these, the halogen atom is preferred, and a fluorine atom is more preferred.

R^{B5}, R^{B6}, R^{B7}, R^{B9} and R^{B10} each represent preferably an unsubstituted linear or branched monovalent alkyl group, a monovalent fluorinated alkyl group, an unsubstituted monovalent aromatic hydrocarbon group, —OSO₂—R^{k}, or —SO₂—R^{k}, more preferably the monovalent fluorinated alkyl group or the unsubstituted monovalent aromatic hydrocarbon group, and still more preferably the monovalent fluorinated alkyl group.

In the formula (r-a), b3 is preferably 0 to 2, more preferably 0 or 1, and still more preferably 0; and n_{bb} is preferably 0 or 1, and more preferably 0. In the formula (r-b), b4 is preferably 0 to 2, more preferably 0 or 1, and still more preferably 0; b5 is preferably 0 to 2, more preferably 0 or 1, and still more preferably 0; n_{b2} is preferably 2 or 3, and more preferably 2; and n_{b1} is preferably 0 or 1, and more preferably 0. In the formula (r-c), b6 and b7 are each preferably 0 to 2, more preferably 0 or 1, and still more preferably 0.

Of these, T⁺ represents preferably the cation (r-a), and more preferably a triphenylsulfonium cation.

The acid generating agent (B) is exemplified by compounds represented by the following formulae (5-1) to (5-5) (hereinafter, may be also referred to as “compounds (5-1) to (5-5)”) as an acid generating agent which generates sulfonic acid.

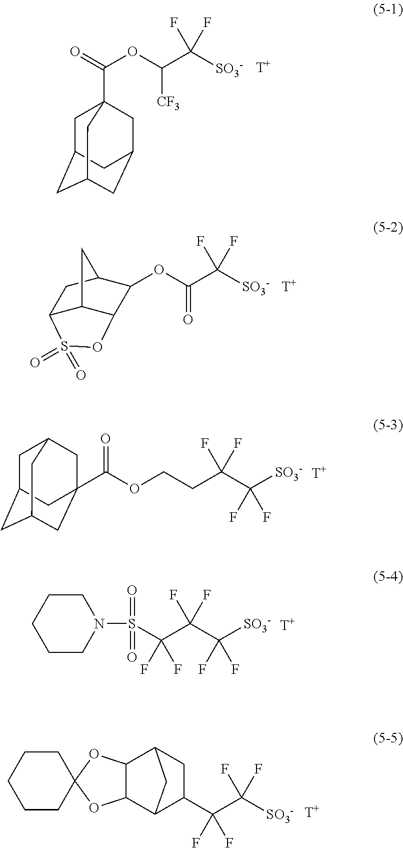

In the above formulae (5-1) to (5-5), T⁺ represents a monovalent radiation-sensitive onium cation.

In the case in which the acid generator (B) is the acid generating agent (B), the lower limit of a content of the acid generating agent (B) in the radiation-sensitive resin composition is, with respect to 100 parts by mass of the polymer (A), preferably 0.1 parts by mass, more preferably 1 part by mass, and still more preferably 5 parts by mass. The upper limit of the content is preferably 70 parts by mass, more preferably 50 parts by mass, still more preferably 40 parts by mass, and particularly preferably 30 parts by mass. When the content of the acid generating agent (B) falls within the above range, the sensitivity to exposure light and the LWR performance of the resist pattern formed by the radiation-sensitive resin composition can be even further improved, and the process window can be even further expanded.

### (C) Compound

The compound (C) is represented by the following formula (2). The compound (C) acts as the acid diffusion control agent. The acid diffusion control agent is able to control a diffusion phenomenon in the resist film of the acid generated from the acid generator (B) and the like upon exposure, thereby serving to inhibit unwanted chemical reactions in an unexposed region. Due to the compound (C) being contained, the radiation-sensitive resin composition enables a resist pattern to be formed with favorable sensitivity to exposure light, superiority with regard to LWR performance, and a broad process window.

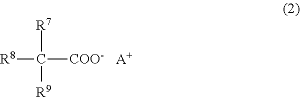

In the above formula (2),

R⁷, R⁸, and R⁹ each independently represent a hydrogen atom, a fluorine atom, or a monovalent organic group having 1 to 40 carbon atoms, or two or more of R⁷, R⁸, and R⁹ taken together represent a part of a ring structure having 3 to 20 ring atoms constituted together with the carbon atom to which the two or more of R⁷, R⁸, and R⁹ bond; and

A⁺ represents a monovalent radiation-sensitive onium cation.

Examples of the monovalent organic group having 1 to 40 carbon atoms which may be represented by R⁷, R⁸, or R⁹ include groups similar to the monovalent organic groups exemplified as R¹² in the above formula (3), and the like.

The ring structure having 3 to 20 ring atoms constituted by the two or more of R⁷, R⁸, and R⁹ taken together with the carbon atom to which the two or more of R⁷, R⁸, and R⁹ bond is exemplified by an alicyclic structure having 3 to 20 ring atoms, an aliphatic heterocyclic structure having 4 to 20 ring atoms, an aromatic carbocyclic structure having 6 to 20 ring atoms, an aromatic heterocyclic structure having 6 to 20 ring atoms, and the like.

Examples of the alicyclic structure having 3 to 20 ring atoms, the aliphatic heterocyclic structure having 4 to 20 ring atoms, the aromatic carbocyclic structure having 6 to 20 ring atoms, and the aromatic heterocyclic structure having 6 to 20 ring atoms include ring structures similar to, respectively, the alicyclic structure, the aliphatic heterocyclic structure, the aromatic carbocyclic structure, and the aromatic heterocyclic structure, and the like.

Examples of the monovalent radiation-sensitive onium cation represented by A⁺ include the monovalent radiation-sensitive onium cation exemplified as T⁺ in the above formula (5), and the like.

It is preferable that at least one of R⁷, R⁸, and R⁹ is a fluorine atom, more preferable that at least two of R⁷, R⁸, and R⁹ are fluorine atoms, and still more preferable that R⁷ and R⁹ are fluorine atoms.

R⁸ represents preferably the monovalent organic group having 1 to 40 carbon atoms. Of monovalent organic groups, R⁸ represents more preferably a monovalent organic group having 1 to 40 carbon atoms, and containing a hetero atom other than a fluorine atom. Examples of the hetero atom other than a fluorine atom include a nitrogen atom, an oxygen atom, a sulfur atom, and the like; and an oxygen atom is preferable. R⁸ represents still more preferably a monovalent organic group having 1 to 40 carbon atoms, and containing at least one selected from an ester structure, a ketone structure, and a hydroxyl group. Furthermore, it is also preferable for R⁸ to represent a monovalent organic group having 1 to 40 carbon atoms, and containing a ring structure. Examples of such a ring structure include an alicyclic structure, an aromatic carbocyclic structure, an aliphatic heterocyclic structure, an aromatic heterocyclic structure, and the like; and specific ring structures are similar to those described above. Of these, the ring structure is preferably an alicyclic structure, and more preferably a cycloalkyl ring or an adamantane ring. Alternatively, it is also preferable for R⁸ to represent a monovalent organic group having 1 to 40 carbon atoms, and not including a fluorine atom. It is particularly preferable for R⁷ and R⁹ to represent fluorine atoms, and for R⁸ to be in such a mode.

A⁺ is preferably the cation (r-a), the cation (r-b), or the cation (r-c), more preferably the cation (r-a) or the cation (r-b), still more preferably the cation (r-a), and particularly preferably a triphenylsulfonium cation.

Examples of the compound (C) include compounds represented by the following formulae (2-1) to (2-15) (hereinafter, may be also referred to as “compounds (2-1) to (2-15)”), and the like.

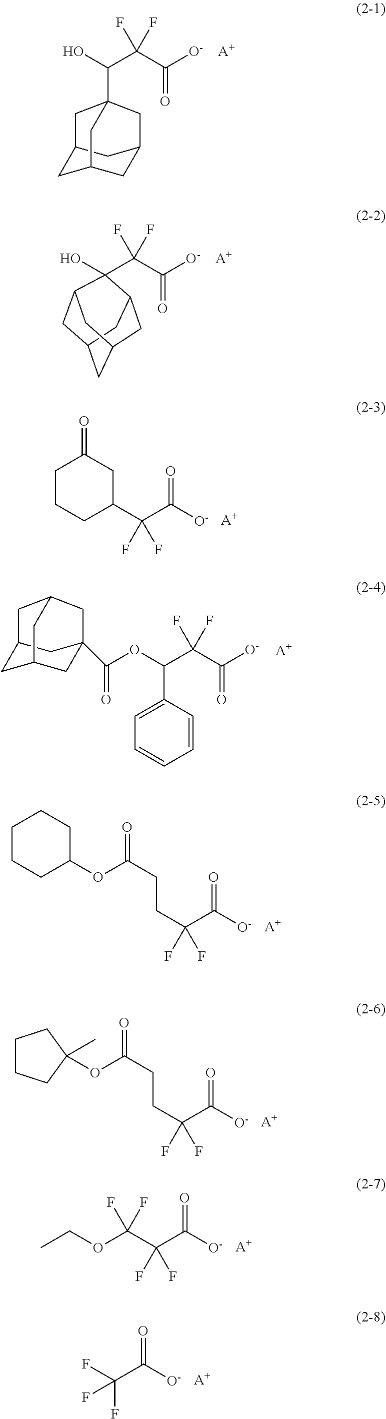

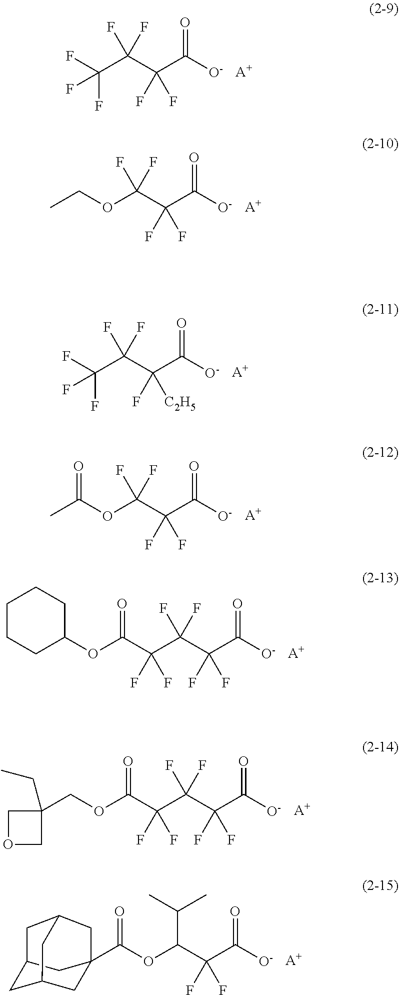

In the above formulae (2-1) to (2-15), A⁺ is as defined in the above formula (2).

As the compound (C), any of the compounds (2-1) to (2-7) is preferred.

The lower limit of a proportion of the compound (C) contained in the radiation-sensitive resin composition with respect to 100 mol % of the acid generating agent (B) is preferably 1 mol %, more preferably 5 mol %, and still more preferably 10 mol %. The upper limit of the proportion is preferably 200 mol %, more preferably 100 mol %, and still more preferably 50 mol %. When the proportion of the compound (C) falls within the above range, with regard to the resist pattern formed by the radiation-sensitive resin composition, the sensitivity to exposure light and the LWR performance can be further improved, and the process window can be further expanded.

### (D) Organic Solvent

The radiation-sensitive resin composition typically contains the organic solvent (D). The organic solvent (D) is not particularly limited as long as it is a solvent capable of dissolving or dispersing at least the polymer (A), the acid generator (B), and the compound (C), as well as the optional component(s) which is/are contained as desired.

The organic solvent (D) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol-1-monomethyl ether; and the like.

Examples of the ether solvent include:

dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

lactone solvents such as γ-butyrolactone and valerolactone;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the alcohol solvent or the ester solvent is preferred, the polyhydric alcohol partial ether solvent having 3 to 19 carbon atoms or the polyhydric alcohol partial ether carboxylate solvent is more preferred, and propylene glycol-1-monomethyl ether or propylene glycol monomethyl ether acetate is still more preferred. One, or two or more types of the organic solvent (D) may be contained.

In the case of the organic solvent (D) being contained in the radiation-sensitive resin composition, the lower limit of a proportion of the organic solvent (D) with respect to all components is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

Other Optional Component(s) The other optional component(s) is/are exemplified by an acid diffusion controller other than the compound (C), a surfactant, and the like. The radiation-sensitive resin composition may contain one, or two or more types each of the other optional component(s).

Acid Diffusion Controller Other than Compound (C)

The acid diffusion controller other than the compound (C) may be contained in the radiation-sensitive resin composition either in the form of a low-molecular-weight compound (hereinafter, may be also referred to as “other acid diffusion control agent”) or in the form of an acid diffusion controller incorporated as a part of a polymer such as the polymer (A), or may be in a combination of both these forms.

The other acid diffusion control agent is exemplified by a nitrogen atom-containing compound, a photodegradable base that is photosensitized by an exposure to generate a weak acid (except for those corresponding to the compound (C)), and the like.

Examples of the nitrogen atom-containing compound include:

amine compounds such as tripentylamine and trioctylamine;

amide group-containing compounds such as formamide and N,N-dimethylacetamide;

urea compounds such as urea and 1,1-dimethylurea;

nitrogen-containing heterocyclic compounds such as pyridine, N-(undecylcarbonyloxyethyl)morpholine and N-t-pentyloxycarbonyl-4-hydroxypiperidine; and the like.

Examples of the photodegradable base include a compound containing: an onium cation degraded by exposure; and an anion of a weak acid (except for those corresponding to the compound (C)), and the like.

In the case of the other acid diffusion control agent being contained in the radiation-sensitive resin composition, the lower limit of a proportion of the acid diffusion control agent contained in the radiation-sensitive resin composition with respect to 100 mol % of the acid generating agent (B) is preferably 1 mol %, more preferably 5 mol %, and still more preferably 10 mol %. The upper limit of the proportion is preferably 200 mol %, more preferably 100 mol %, and still more preferably 50 mol %.

Surfactant

The surfactant achieves the effect of improving the coating characteristics, striation, developability, and the like. Examples of the surfactant include nonionic surfactants such as polyoxyethylene lauryl ether, polyoxyethylene stearyl ether, polyoxyethylene oleyl ether, polyoxyethylene n-octyl phenyl ether, polyoxyethylene n-nonyl phenyl ether, polyethylene glycol dilaurate, and polyethylene glycol distearate; and the like. Commercially available products such as “KP341” (available from Shin-Etsu Chemical Co., Ltd.), “Polyflow No. 75” and “Polyflow No. 95” (available from Kyoeisha Chemical Co., Ltd.), “EFTOP EF301,” “EFTOP EF303,” and “EFTOP EF352” (available from Tohkem Products Corporation (Mitsubishi Materials Electronic Chemicals Co., Ltd.)), “MEGAFAC F171” and “MEGAFAC F173” (available from Dainippon Ink and Chemicals, Inc.), “Fluorad FC430” and “Fluorad FC431” (available from Sumitomo 3M Ltd.), “Asahi Guard AG710,” “Surflon S-382,” “Surflon SC-101,” “Surflon SC-102,” “Surflon SC-103.” “Surflon SC-104,” “Surflon SC-105,” and “Surflon SC-106” (manufactured by Asahi Glass Co., Ltd.), and the like can be exemplified.

In the case of the surfactant being contained in the radiation-sensitive resin composition, the upper limit of a content of the surfactant in the radiation-sensitive resin composition with respect to 100 parts by mass of the polymer (A) is preferably 2 parts by mass. The lower limit of the content is, for example, 0.1 parts by mass.

### Preparation Procedure of Radiation-Sensitive Resin Composition

The radiation-sensitive resin composition of the embodiment of the present invention may be prepared, for example, by mixing the polymer (A), the acid generator (B), and the compound (C), as well as the optional component(s) such as organic solvent (D), the other optional component(s), and the like, which are added as needed, in a certain ratio, and preferably filtering a thus resulting mixture through a membrane filter having a pore size of no greater than 0.2 μm.

The radiation-sensitive resin composition may be used either for positive-tone pattern formation conducted using an alkaline developer solution, or for negative-tone pattern formation conducted using an organic solvent-containing developer solution.

The radiation-sensitive resin composition is for exposure by irradiation with a radioactive ray (exposure light) in the exposing step of the resist pattern-forming method, to be described later. Of types of exposure light, an extreme ultraviolet ray (EUV) or an electron beam has comparatively high energy, but the radiation-sensitive resin composition enables a resist pattern to be formed with favorable sensitivity to exposure light, superiority with regard to LWR performance, and a broad process window, even in the case of using the extreme ultraviolet ray or the electron beam as the exposure light. Accordingly, the radiation-sensitive resin composition can be particularly suitably used for exposure with an extreme ultraviolet ray or exposure with an electron beam.

### Resist Pattern-Forming Method

The resist pattern-forming method according to an embodiment of the present invention includes: a step of applying the radiation-sensitive resin composition according to the embodiment of the invention directly or indirectly on a substrate (hereinafter, may be also referred to as “applying step”); a step of exposing a resist film formed by the applying step (hereinafter, may be also referred to as “exposing step”); and a step of developing the resist film exposed (hereinafter, may be also referred to as “developing step”).

According to the resist pattern-forming method, due to use of the radiation-sensitive resin composition in the applying step, formation of a resist pattern having favorable sensitivity to exposure light, superiority with regard to the LWR performance, and a broad process window is enabled.

Hereinafter, each step included in the resist pattern-forming method will be described.

Applying Step

In this step, the radiation-sensitive resin composition according to the embodiment of the invention is applied directly or indirectly on a substrate to thereby form a resist film. The substrate is exemplified by a conventionally well-known substrate such as a silicon wafer, a wafer coated with silicon dioxide or aluminum, and the like. In addition, as an underlayer film, an organic or inorganic antireflective film disclosed in, for example, Japanese Examined Patent Application, Publication No. H6-12452, Japanese Unexamined Patent Application, Publication No. S59-93448, or the like may be provided on the substrate. An application procedure is exemplified by spin-coating, cast coating, roll-coating, and the like. After the application, prebaking (PB) may be carried out as needed for evaporating the solvent remaining in the coating film. The lower limit of a temperature of the PB is preferably 60° C., and more preferably 80° C. The upper limit of the temperature of the PB is preferably 150° C., and more preferably 140° C. The lower limit of a time period of the PB is preferably 5 sec, and more preferably 10 sec. The upper limit of the time period of the PB is preferably 600 sec, and more preferably 300 sec. The lower limit of an average thickness of the resist film formed is preferably 10 nm, and more preferably 20 nm. The upper limit of the average thickness is preferably 1,000 nm, and more preferably 500 nm.

Exposing Step

In this step, the resist film formed by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays, and γ-rays; charged particle rays such as electron beams and α-rays; and the like, which may be selected in accordance with a line width of the intended pattern, and the like. Of these, far ultraviolet rays, EUV, or electron beams are preferred; an ArF excimer laser beam (wavelength: 193 nm), a KrF excimer laser beam (wavelength: 248 nm), EUV, or an electron beam is more preferred; an ArF excimer laser beam, EUV, or an electron beam is still more preferred; and EUV or an electron beam is particularly preferred. It is to be noted that exposure conditions such as exposure dose and the like can be appropriately selected in accordance with a formulation of the radiation-sensitive resin composition, type(s) of additive(s), a type of exposure light, and the like.

It is preferred that post exposure baking (PEB) is carried out after the exposure to promote dissociation of the acid-labile group included in the polymer (A) mediated by the acid generated from the acid generator (B), etc. upon the exposure in exposed regions of the resist film. This PEB enables an increase in a difference in solubility of the resist film in a developer solution between the light-exposed regions and light-unexposed regions. The lower limit of a temperature of the PEB is preferably 50° C., more preferably 80° C., and still more preferably 90° C. The upper limit of the temperature of the PEB is preferably 180° C., and more preferably 130° C. The lower limit of a time period of the PEB is preferably 5 sec, more preferably 10 sec, and still more preferably 30 sec. The upper limit of the time period of the PEB is preferably 600 sec, more preferably 300 sec, and still more preferably 100 sec.

Developing Step

In this step, the resist film exposed is developed. Accordingly, formation of a predetermined resist pattern is enabled. After the development, washing with a rinse agent such as water or an alcohol and then drying is typically performed. The development procedure in the developing step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, trimethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solvent containing the organic solvent; and the like. An exemplary organic solvent includes one, or two or more types of the solvents exemplified as the organic solvent (D) for the radiation-sensitive resin composition, and the like. Of these, the ester solvent or the ketone solvent is preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

The resist pattern to be formed according to the resist pattern-forming method is exemplified by a line-and-space pattern, a hole pattern, and the like.

### EXAMPLES

Hereinafter, the present invention is explained in detail by way of Examples, but the present invention is not in any way limited to these Examples. Measuring methods for various types of physical properties are shown below.

### Weight Average Molecular Weight (Mw), Number Average Molecular Weight (Mn), and Dispersity Index (Mw/Mn)

Measurements of the Mw and the Mn of the polymer were carried out by gel permeation chromatography (GPC) using GPC columns available from Tosoh Corporation (“G2000 HXL”×2, “G3000 HXL”×1, and “G4000 HXL”×1) under the following analytical conditions. Furthermore, a dispersity index (Mw/Mn) was calculated according to measurement results of the Mw and the Mn.

elution solvent: tetrahydrofuran

flow rate: 1.0 mL/min

sample concentration: 1.0% by mass

amount of injected sample: 100 μL

column temperature: 40° C.

detector: differential refractometer

standard substance: mono-dispersed polystyrene

### Proportions of Each Structural Unit in Polymers

Proportions of each structural unit in the polymers were determined by a ¹³C-NMR analysis using a nuclear magnetic resonance apparatus (“JNM-Delta400,” available from JEOL, Ltd.).

### Synthesis of (A) Polymer

Monomers used for synthesizing the polymers in the Examples and Comparative Examples are presented below. It is to be noted that in the following Synthesis Examples, unless otherwise specified particularly, “parts by mass” means a value, provided that the total mass of the monomers used was 100 parts by mass, and “mol %” means a value, provided that the total mol number of the monomers used was 100 mol %.

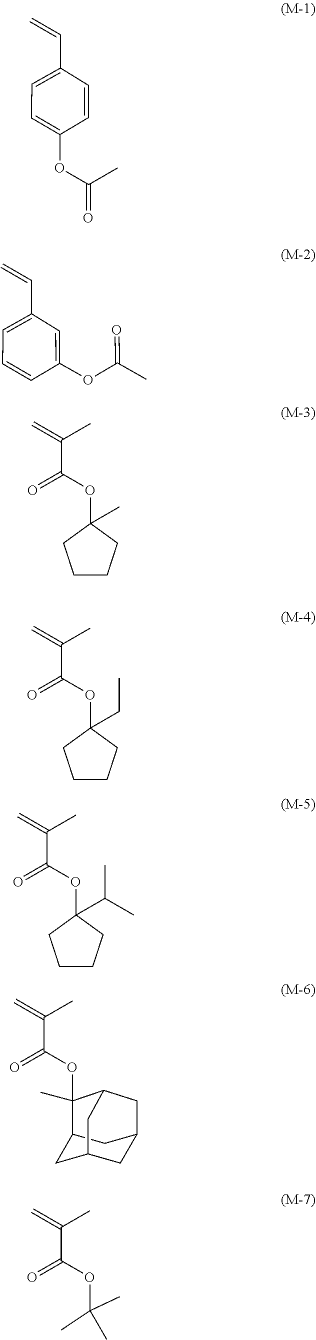

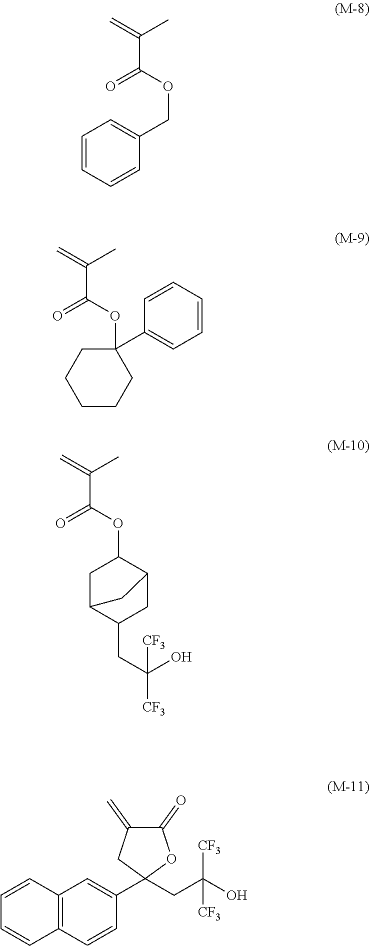 [SMILES: C=C(C)C(=O)OCc1ccccc1 ; C=C(C)C(=O)OC1(c2ccccc2)CCCCC1 ; C=C(C)C(=O)OC1CC2CC1CC2CC(O)(C(F)(F)F)C(F)(F)F ; C=C1CC(CC(O)(C(F)(F)F)C(F)(F)F)(c2ccc3ccccc3c2)OC1=O]

### Synthesis Example 1: Synthesis of Polymer (A-1)

A monomer solution was prepared by: dissolving the monomer (M-1), the monomer (M-3), and the monomer (M-10) in propylene glycol-1-monomethyl ether (200 parts by mass) such that the molar ratio became 40/40/20 (mol %); and adding thereto AIBN as an initiator (6 mol %). Next, propylene glycol-1-monomethyl ether (100 parts by mass) was charged into an empty reaction vessel and heated to 85° C. with stirring. Thereafter, the monomer solution was added dropwise to the reaction vessel over 3 hrs, heating was further conducted at 85° C. for 3 hrs, whereby the polymerization reaction was performed for 6 hrs, and onset of the dropwise addition of the monomer solution was regarded as the time point of the start of the polymerization reaction. After completion of the polymerization reaction, the polymerization solution was cooled to room temperature. The cooled polymerization solution was charged into hexane (500 parts by mass with respect to 100 parts by mass of the polymerization solution), and a thus precipitated white powder was filtered off. The white powder obtained by filtration was washed twice with hexane (100 parts by mass with respect to 100 parts by mass of the polymerization solution), followed by filtering off and dissolution in propylene glycol-1-monomethyl ether (300 parts by mass). Next, methanol (500 parts by mass), triethylamine (50 parts by mass), and ultra-pure water (10 parts by mass) were added to a resulting solution, and a hydrolysis reaction was performed at 70° C. for 6 hrs with stirring. After completion of the hydrolysis reaction, the remaining solvent was distilled away and a solid thus obtained was dissolved in acetone (100 parts by mass). The solution was added dropwise to 500 parts by mass of water to permit coagulation of the resin, a solid thus obtained was filtered off, and drying at 50° C. for 12 hrs gave a white powdery polymer (A-1). The Mw of the polymer (A-1) was 5,600, and the Mw/Mn was 1.62. Furthermore, as a result of the ¹³C-NMR analysis, the proportions of the structural units derived from (M-1), (M-3), and (M-10) were, respectively, 42.3 mol %, 39.8 mol %, and 17.9 mol %.

### Synthesis Examples 2 to 8: Synthesis of Polymer (A-2) to Polymer (A-8)

Polymers (A-2) to (A-8) were synthesized by a similar operation to that of Synthesis Example 1, except that each monomer of the type and in the blend proportion shown in Table 1 below was used. The proportion of each structural unit, and the physical properties (the Mw and the Mw/Mn) of each polymer thus obtained are shown together in Table 1. It is to be noted that in Table 1, “-” indicates that the corresponding monomer was not used.

### Synthesis Example 9: Synthesis of Polymer (A-9)

Using the type and physical properties of the monomer shown in Table 1 below, polymer (A-9) was synthesized by a procedure similar to the synthesis procedure of “polymer (B-3-1)” described in Japanese Unexamined Patent Publication, Publication No. 2009-244805. The proportion of each structural unit, and the physical properties (the Mw and the Mw/Mn) of the polymer thus obtained are shown together in Table 1.

TABLE 1

| | | Monomer that gives | | | Monomer that gives | | | Monomer that gives | | | Monomer that gives | | | | |
|---|---|---|---|---|---|---|---|---|---|---|---|---|---|---|---|
| | | first structural unit | | | second structural unit | | | third structural unit | | | other structural unit(s) | | | | |
| | | | | propor- | | | propor- | | | propor- | | | propor- | | |
| | | | blend | tion | | blend | tion | | blend | tion | | blend | tion | | |
| | | | propor- | of | | propor- | of | | propor- | of | | propor- | of | Physical | |
| | (A) | | tion | structural | | tion | structural | | tion | structural | | tion | structural | properties | |
| | Poly- | | (mol | unit | | (mol | unit | | (mol | unit | | (mol | unit | | Mw/ |
| | mer | type | %) | (mol %) | type | %) | (mol %) | type | %) | (mol %) | type | %) | (mol %) | Mw | Mn |
| Example 1 | A-1 | M-1 | 40 | 42.3 | M-10 | 20 | 17.9 | M-3 | 40 | 39.8 | — | — | — | 5,600 | 1.62 |
| Example 2 | A-2 | M-1 | 40 | 43.1 | M-10 | 20 | 18.2 | M-4 | 40 | 38.7 | — | — | — | 5,800 | 1.65 |
| Example 3 | A-3 | M-1 | 20 | 22.2 | M-10 | 20 | 20.7 | M-5 | 40 | 37.8 | — | — | — | 6,100 | 1.59 |
| | | M-2 | 20 | 19.3 | | | | | | | | | | | |
| Example 4 | A-4 | M-1 | 40 | 42.3 | M-11 | 20 | 21.2 | M-6 | 40 | 36.5 | — | — | — | 5,900 | 1.51 |
| Example 5 | A-5 | M-1 | 40 | 42.1 | M-11 | 20 | 20 | M-9 | 40 | 37.9 | — | — | — | 5,700 | 1.62 |
| Example 6 | A-6 | M-1 | 40 | 41.1 | M-10 | 40 | 39.8 | M-5 | 20 | 19.1 | — | — | — | 5,800 | 1.67 |
| Example 7 | A-7 | M-1 | 40 | 43.2 | M-10 | 20 | 19.6 | M-5 | 40 | 37.2 | — | — | — | 6,000 | 1.54 |
| Example 8 | A-8 | M-1 | 40 | 43.9 | M-10 | 5 | 5 | M-5 | 55 | 51.1 | — | — | — | 6,900 | 1.49 |
| Example 9 | A-9 | M-1 | 60 | 59.1 | — | — | — | M-7 | 30 | 30.7 | M-8 | 10 | 10.2 | 12,000 | 1.55 |

### Preparation of Radiation-Sensitive Resin Composition

Components other than the polymer (A) used for preparing the radiation-sensitive resin compositions are shown below. It is to be noted that in the following Examples and Comparative Examples, unless otherwise specified particularly, “parts by mass” means a value, provided that the mass of the polymers used was 100 parts by mass, and “mol %” means a value, provided that the total mol number of the acid generating agent (B) used was 100 mol %.

(B) Acid Generating Agent

B-1 to B-4: Compounds Represented by the Following Formulae (B-1) to (B-4)

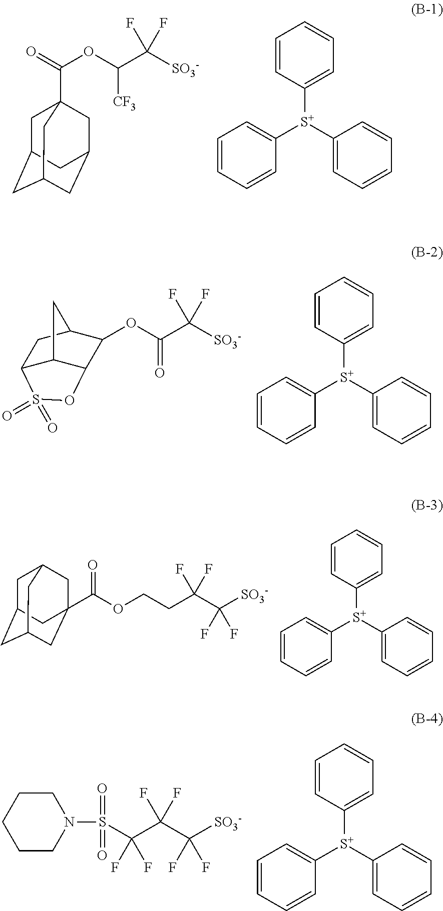

(C) Acid Diffusion Control Agent

C-1 to C-9: Compounds Represented by the Following Formulae (C-1) to (C-9)

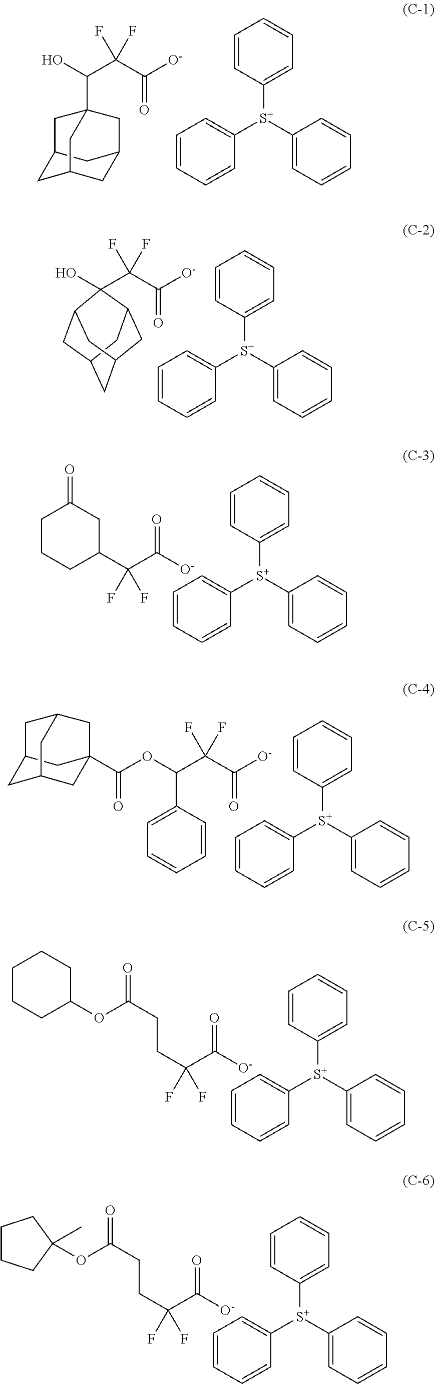

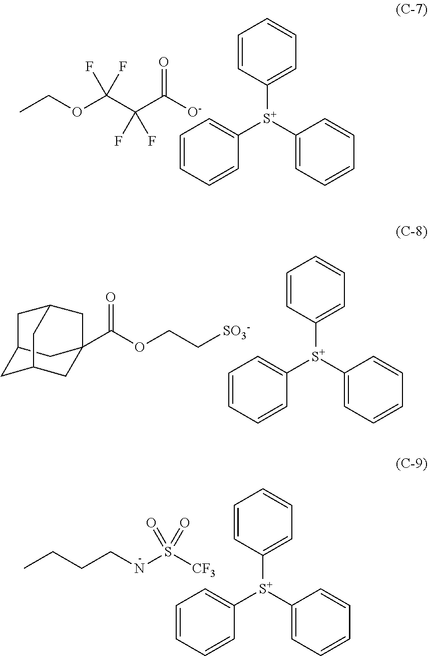

(D) Organic Solvent

D-1: Propylene Glycol Monomethyl Ether Acetate

D-2: Propylene Glycol-1-Monomethyl Ether

### Example 1

A radiation-sensitive resin composition (R-1) was prepared by: mixing 100 parts by mass of (A-1) as the polymer (A), 20 parts by mass of (B-1) as the acid generating agent (B), mol % of (C-1) as the acid diffusion control agent (C), and 4,800 parts by mass of (D-1) and 2,000 parts by mass of (D-2) as the organic solvent (D), and filtering a thus resulting mixture through a membrane filter having a pore size of 0.2 m.

### Examples 2 to 14 and Comparative Examples 1 to 3

Radiation-sensitive resin compositions (R-2) to (R-14) and (CR-1) to (CR-3) were prepared in a similar manner to Example 1, except that for each component, the type and content shown in Table 2 below were used.

TABLE 2

| | | | | (B) Acid | | (C) Acid diffusion | | | |
|---|---|---|---|---|---|---|---|---|---|
| | Radiation- | (A) Polymer | | generating agent | | control agent | | (D) Organic solvent | |
| | sensitive | | content | | content | | blend | | content |
| | resin | | (parts | | (parts | | proportion | | (parts by |
| | composition | type | by mass) | type | by mass) | type | (mol %) | type | mass) |
| Example 1 | R-1 | A-1 | 100 | B-1 | 20 | C-1 | 20 | D-1/D-2 | 4,800/2,000 |
| Example 2 | R-2 | A-2 | 100 | B-1 | 20 | C-1 | 20 | D-1/D-2 | 4,800/2,000 |
| Example 3 | R-3 | A-3 | 100 | B-2 | 20 | C-1 | 20 | D-1/D-2 | 4,800/2,000 |
| Example 4 | R-4 | A-4 | 100 | B-3 | 20 | C-1 | 20 | D-1/D-2 | 4,800/2,000 |
| Example 5 | R-5 | A-5 | 100 | B-4 | 20 | C-1 | 20 | D-1/D-2 | 4,800/2,000 |
| Example 6 | R-6 | A-6 | 100 | B-2 | 20 | C-1 | 20 | D-1/D-2 | 4,800/2,000 |
| Example 7 | R-7 | A-7 | 100 | B-3 | 20 | C-1 | 20 | D-1/D-2 | 4,800/2,000 |
| Example 8 | R-8 | A-8 | 100 | B-2 | 20 | C-1 | 20 | D-1/D-2 | 4,800/2,000 |
| Example 9 | R-9 | A-7 | 100 | B-2 | 20 | C-2 | 20 | D-1/D-2 | 4,800/2,000 |
| Example 10 | R-10 | A-7 | 100 | B-2 | 20 | C-3 | 20 | D-1/D-2 | 4,800/2,000 |
| Example 11 | R-11 | A-7 | 100 | B-2 | 20 | C-4 | 20 | D-1/D-2 | 4,800/2,000 |
| Example 12 | R-12 | A-7 | 100 | B-2 | 20 | C-5 | 20 | D-1/D-2 | 4,800/2,000 |
| Example 13 | R-13 | A-7 | 100 | B-2 | 20 | C-6 | 20 | D-1/D-2 | 4,800/2,000 |
| Example 14 | R-14 | A-7 | 100 | B-2 | 20 | C-7 | 20 | D-1/D-2 | 4,800/2,000 |
| Comparative | CR-1 | A-9 | 100 | B-1 | 20 | C-1 | 20 | D-1/D-2 | 4,800/2,000 |
| Example 1 | | | | | | | | | |
| Comparative | CR-2 | A-1 | 100 | B-1 | 20 | C-8 | 20 | D-1/D-2 | 4,800/2,000 |
| Example 2 | | | | | | | | | |
| Comparative | CR-3 | A-1 | 100 | B-1 | 20 | C-9 | 20 | D-1/D-2 | 4,800/2,000 |
| Example 3 | | | | | | | | | |

### Resist Pattern Formation (EUV Exposure, Alkali Development)

An underlayer film (“AL412,” available from Brewer Science, Inc.) having an average thickness of 20 nm was formed on a 12-inch silicon wafer, the radiation-sensitive resin compositions prepared as described above were each applied on the underlayer film using a spin coater (“CLEAN TRACK ACT12,” available from Tokyo Electron Limited), and soft-baking (SB) was conducted at 130° C. for 60 sec. Thereafter, by cooling at 23° C. for 30 sec, a resist film having an average thickness of 50 nm was formed. Next, the resist film was exposed using an EUV scanner (“NXE3300”, available from ASML Co.) with NA of 0.33 under an illumination condition of Conventional s=0.89 and with a mask of imecDEFECT32FFR02. After the exposing, the resist film was developed at 23° C. for 30 sec by using a 2.38% by mass aqueous TMAH solution as an alkaline developer solution to form a positive-tone resist pattern (32 nm line-and-space pattern).

### Evaluations

The resist patterns formed were evaluated on sensitivity, LWR performance, and process windows in accordance with the following methods. It is to be noted that a scanning electron microscope (“CG-4100,” available from Hitachi High-Technologies Corporation) was used for line-width measurement of the resist pattern. The results of the evaluations are shown in Table 3 below. It is to be noted that “-” in Table 3 below indicates that in Comparative Example 2, a resist pattern failed to be formed due to dissolution in the alkaline developer solution extending to light-unexposed regions, and it was not possible to conduct each type of evaluation.

Sensitivity

An exposure dose at which a 32-nm line-and-space pattern was formed in the aforementioned resist pattern formation was defined as an optimum exposure dose, and this optimum exposure dose was adopted as sensitivity (mJ/cm²). The sensitivity may be evaluated to be: “favorable” in a case of being no greater than 30 mJ/cm²; and “unfavorable” in a case of being greater than 30 mJ/cm².

LWR Performance

The resist patterns formed were observed from above using the scanning electron microscope. Line widths were measured at 50 arbitrary points, and then a 3 Sigma value was determined from distribution of the measurements, and the 3 Sigma value was defined as “LWR (nm).” The value being smaller reveals less line rattling, indicating better LWR performance. The LWR performance may be evaluated to be: “favorable” in a case of being no greater than 4.0 nm; and “unfavorable” in a case of being greater than 4.0 nm.

Process Window

The “process window” as referred to herein means the range of resist dimensions at which a pattern having no bridge defects or collapses can be formed. Using a mask for forming a 32-nm line-and-space pattern (1L/1S), patterns were formed with low-exposure doses to high-exposure doses. In general, defects in bridge formation and the like can be found in patterns in the case of the low-exposure dose, and defects such as pattern collapses can be found in the case of the high-exposure dose. The difference between the maximum value and the minimum value of resist dimensions at which no such defects were found was considered to be the “CD (Critical Dimension) margin.” The CD margin being large reveals a broader process window, and is favorable. The CD margin may be evaluated to be: “favorable” in a case of being no less than 30 nm; and “unfavorable” in a case of being less than 30 nm.

TABLE 3

| | Radiation-sensitive | Sensitivity | | CD |
|---|---|---|---|---|
| | resin composition | (mJ/cm²) | LWR (nm) | margin (nm) |
| Example 1 | R-1 | 26 | 3.7 | 38 |
| Example 2 | R-2 | 27 | 3.6 | 37 |
| Example 3 | R-3 | 28 | 3.6 | 38 |
| Example 4 | R-4 | 29 | 3.7 | 42 |
| Example 5 | R-5 | 28 | 3.7 | 41 |
| Example 6 | R-6 | 25 | 3.7 | 32 |
| Example 7 | R-7 | 27 | 3.6 | 36 |
| Example 8 | R-8 | 29 | 3.6 | 39 |
| Example 9 | R-9 | 27 | 3.6 | 37 |
| Example 10 | R-10 | 29 | 3.6 | 42 |
| Example 11 | R-11 | 26 | 3.8 | 40 |
| Example 12 | R-12 | 27 | 3.8 | 41 |
| Example 13 | R-13 | 25 | 3.6 | 43 |
| Example 14 | R-14 | 25 | 3.8 | 38 |
| Comparative | CR-1 | 40 | 4.3 | 25 |
| Example 1 | | | | |
| Comparative | CR-2 | — | — | — |
| Example 2 | | | | |
| Comparative | CR-3 | 52 | 4.0 | 25 |
| Example 3 | | | | |

As is clear from the results shown in Table 3, when compared to the radiation-sensitive resin compositions of the Comparative Examples, the radiation-sensitive resin compositions of the Examples were favorable in terms of each of sensitivity, LWR performance, and CD margins.

The radiation-sensitive resin composition and the resist pattern-forming method of the embodiments of the present invention enable a resist pattern to be formed with favorable sensitivity to exposure light, superiority with regard to LWR performance, and a broad process window. Therefore, these can be suitably used in manufacturing processes of semiconductor devices and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a polymer comprising:
a first structural unit comprising a phenolic hydroxyl group;
a second structural unit comprising a group represented by formula (1); and
a third structural unit comprising an acid-labile group;
a radiation-sensitive acid generator; and
a compound represented by formula (2), 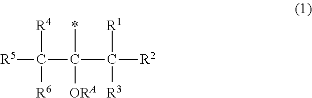
wherein, in the formula (1),
R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, wherein at least one of R¹, R², R³, R⁴, R⁵, and R⁶ represents a fluorine atom or a fluorinated hydrocarbon group;
R^{A} represents a hydrogen atom or a monovalent organic group having 1 to 20 carbon atoms; and
* denotes a binding site to a part other than the group represented by the formula (1) in the second structural unit, and 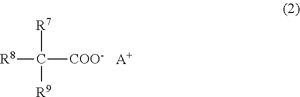
in the formula (2),
R⁷, R⁸, and R⁹ each independently represent a hydrogen atom, a fluorine atom, or a monovalent organic group having 1 to 40 carbon atoms, and optionally two or more of R⁷, R⁸, and R⁹ taken together represent a ring structure having 3 to 20 ring atoms together with the carbon atom to which the two or more of R⁷, R⁸, and R⁹ bond; and
A⁺ represents a monovalent radiation-sensitive onium cation.

2. The radiation-sensitive resin composition according to claim 1, wherein at least one of R⁷, R⁸, and R⁹ in the formula (2) represents a fluorine atom.

3. The radiation-sensitive resin composition according to claim 2, wherein in the formula (2),
R⁷ and R⁹ each represent a fluorine atom, and
R⁸ represents a monovalent organic group having 1 to 40 carbon atoms and comprising a hetero atom other than a fluorine atom; a monovalent organic group having 1 to carbon atoms and comprising an ester structure, a ketone structure, a hydroxyl group, or a combination thereof, or a monovalent organic group having 1 to 40 carbon atoms and not comprising a fluorine atom.

4. The radiation-sensitive resin composition according to claim 1, wherein
a proportion of the third structural unit contained in the polymer with respect to total structural units constituting the polymer is no less than 30 mol % and no greater than 80 mol %.

5. The radiation-sensitive resin composition according to claim 1, wherein the first structural unit is represented by formula (3): 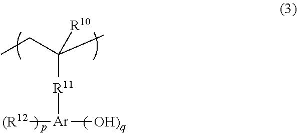
wherein, in the formula (3),
R¹⁰ represents a hydrogen atom, a fluorine atom, a methyl group, or a trifluoromethyl group;
R¹¹ represents a single bond, —O—, —COO—, or —CONH—;
Ar represents a group obtained by removing (p+q+1) hydrogen atoms from an aromatic ring of an arene having 6 to 20 ring atoms;
p is an integer of 0 to 10, wherein in a case in which p is 1, R¹² represents a monovalent organic group having 1 to 20 carbon atoms or a halogen atom, and in a case in which p is no less than 2, a plurality of R¹²s are identical or different from each other, and each R¹² represents a halogen atom or a monovalent organic group having 1 to 20 carbon atoms, and optionally two or more of the plurality of R¹²s taken together represent a ring structure having 4 to 20 ring atoms together with the carbon chain to which the two or more of the plurality of R¹²s bond; and
q is an integer of 1 to 11, wherein
a sum of p and q is no greater than 11.

6. The radiation-sensitive resin composition according to claim 1, wherein the third structural unit is represented by formula (4-1A), (4-1B), (4-1C), (4-2A), or (4-2B): 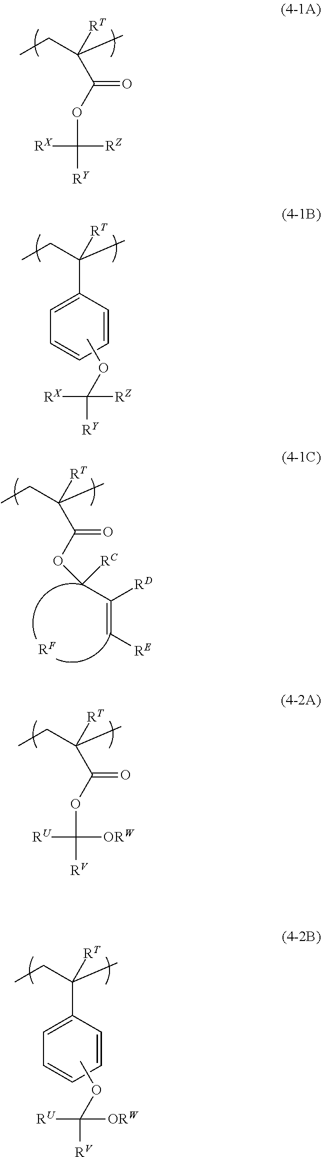
wherein, in each of the formulae (4-1A), (4-1B), (4-1C), (4-2A), and (4-2B),
R^{T} represents a hydrogen atom, a fluorine atom, a methyl group, or a trifluoromethyl group,
in each of the formulae (4-1A) and (4-1B),
R^{X} represents a hydrogen atom or a monovalent hydrocarbon group having 1 to 20 carbon atoms; and
R^{Y} and R^{Z} each independently represent a monovalent hydrocarbon group having 1 to 20 carbon atoms, or R^{Y} and R^{Z} taken together represent an alicyclic structure having 3 to ring atoms together with the carbon atom to which R^{Y} and R^{Z} bond,
in the formula (4-1C),
R^{C} represents a hydrogen atom;
R^{D} and R^{E} each independently represent a hydrogen atom or a monovalent hydrocarbon group having 1 to 20 carbon atoms; and
R^{F} represents a divalent hydrocarbon group having 1 to 20 carbon atoms constituting an unsaturated alicyclic structure having 4 to 20 ring atoms together with the carbon atom to which each of R^{C}, R^{D}, and R^{E} bond, and
in each of the formulae (4-2A) and (4-2B),
R^{U} and R^{V} each independently represent a hydrogen atom or a monovalent hydrocarbon group having 1 to 20 carbon atoms, and R^{W} represents a monovalent hydrocarbon group having 1 to 20 carbon atoms, and optionally
R^{U} and R^{V} taken together represent an alicyclic structure having 3 to 20 ring atoms together with the carbon atom to which R^{U} and R^{V} bond, or R^{U} and R^{W} taken together represent an aliphatic heterocyclic structure having 5 to 20 ring atoms together with the carbon atom to which R^{U} bonds and the oxygen atom to which R^{W} bonds.

7. The radiation-sensitive resin composition according to claim 1, wherein in the formula (1), R¹, R², R³, R⁴, R⁵, and R⁶ each represent a fluorine atom; and R^{A} represents a hydrogen atom.

8. The radiation-sensitive resin composition according to claim 1, wherein the second structural unit is represented by formula (1-1) or formula (1-2): 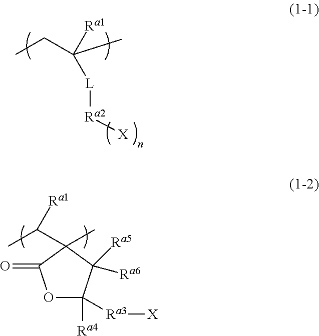
wherein in each of the formulae (1-1) and (1-2),
R^{a1} represents a hydrogen atom, a fluorine atom, a methyl group, or a trifluoromethyl group; and X represents the group represented by the formula (1),
in the formula (1-1), L represents a single bond or —COO—; R^{a2} represents a monovalent organic group having a valency of (n+1) and having 1 to 20 carbon atoms; and n is an integer of 1 to 3, wherein in a case in which n is no less than 2, a plurality of Xs are identical or different from each other, and
in the formula (1-2), R^{a3} represents a divalent hydrocarbon group having 1 to 20 carbon atoms; R^{a4} represents a monovalent hydrocarbon group having 1 to 20 carbon atoms; and R^{a5} and R^{a6} each independently represent a hydrogen atom or a monovalent hydrocarbon group having 1 to 10 carbon atoms, or R^{a5} and R^{a6} taken together represent a ring structure having 3 to 20 ring atoms, together with the carbon atom to which R^{a5} and R^{a6} bond.

9. The radiation-sensitive resin composition according to claim 8, wherein in the formula (1), R¹, R², R³, R⁴, R⁵, and R⁶ each represent a fluorine atom; and R^{A} represents a hydrogen atom, and in the formula (1-2), R^{a2} represents an alicyclic saturated hydrocarbon group.

10. The radiation-sensitive resin composition according to claim 1 which is suitable for an exposure to an extreme ultraviolet ray or an exposure to an electron beam.

11. A resist pattern-forming method comprising:
applying a radiation-sensitive resin composition directly or indirectly on a substrate to form a resist film directly or indirectly on the substrate;
exposing the resist film; and
developing the resist film exposed,
wherein the radiation-sensitive resin composition comprises:
a polymer comprising:
a first structural unit comprising a phenolic hydroxyl group;
a second structural unit comprising a group represented by formula (1);
and a third structural unit comprising an acid-labile group;
a radiation-sensitive acid generator; and
a compound represented by formula (2), 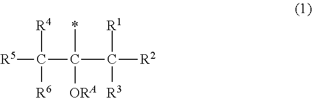
wherein, in the formula (1),
R¹, R², R³, R⁴, R⁵, and R⁶ each independently represent a hydrogen atom, a fluorine atom, a chlorine atom, a bromine atom, an iodine atom, or a monovalent fluorinated hydrocarbon group having 1 to 10 carbon atoms, and at least one of R¹, R², R³, R⁴, R⁵, and R⁶ represents a fluorine atom or a fluorinated hydrocarbon group;
R^{A} represents a hydrogen atom or a monovalent organic group having 1 to 20 carbon atoms; and
* denotes a binding site to a part other than the group represented by the formula (1) in the second structural unit, and 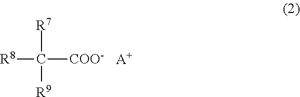
in the formula (2),
R⁷, R⁸, and R⁹ each independently represent a hydrogen atom, a fluorine atom, or a monovalent organic group having 1 to 40 carbon atoms, and optionally two or more of R⁷, R⁸, and R⁹ taken together represent a ring structure having 3 to 20 ring atoms together with the carbon atom to which the two or more of R⁷, R⁸, and R⁹ bond; and
A⁺ represents a monovalent radiation-sensitive onium cation.

12. The resist pattern-forming method according to claim 11, wherein at least one of R⁷, R⁸, and R⁹ in the formula (2) represents a fluorine atom.

13. The resist pattern-forming method according to claim 12, wherein in the formula (2),
R⁷ and R⁹ each represent a fluorine atom, and
R⁸ represents a monovalent organic group having 1 to 40 carbon atoms and comprising a hetero atom other than a fluorine atom; a monovalent organic group having 1 to carbon atoms and comprising an ester structure, a ketone structure, a hydroxyl group, or a combination thereof, or a monovalent organic group having 1 to 40 carbon atoms and not comprising a fluorine atom.

14. The resist pattern-forming method according to claim 11, wherein
a proportion of the third structural unit contained in the polymer with respect to total structural units constituting the polymer is no less than 30 mol % and no greater than 80 mol %.

15. The resist pattern-forming method according to claim 11, wherein the first structural unit is represented by formula (3): 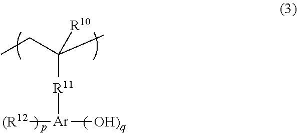
wherein, in the formula (3),
R¹⁰ represents a hydrogen atom, a fluorine atom, a methyl group, or a trifluoromethyl group;
R¹¹ represents a single bond, —O—, —COO—, or —CONH—;
Ar represents a group obtained by removing (p+q+1) hydrogen atoms from an aromatic ring of an arene having 6 to 20 ring atoms;
p is an integer of 0 to 10, wherein in a case in which p is 1, R¹² represents a monovalent organic group having 1 to 20 carbon atoms or a halogen atom, and in a case in which p is no less than 2, a plurality of R¹²s are identical or different from each other, and each R¹² represents a halogen atom or a monovalent organic group having 1 to 20 carbon atoms, and optionally two or more of the plurality of R¹²s taken together represent a ring structure having 4 to 20 ring atoms together with the carbon chain to which the two or more of the plurality of R¹²s bond; and
q is an integer of 1 to 11, wherein
a sum of p and q is no greater than 11.

16. The resist pattern-forming method according to claim 11, wherein the third structural unit is represented by formula (4-1A), (4-1B), (4-1C), (4-2A), or (4-2B): 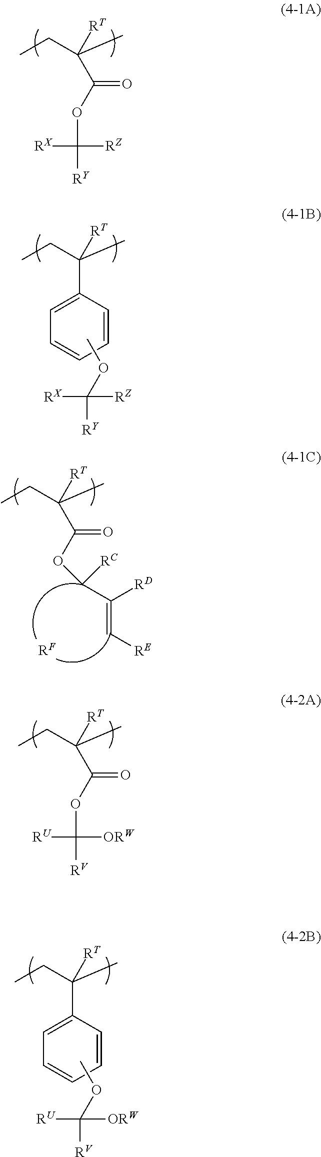
wherein, in each of the formulae (4-1A), (4-1B), (4-1C), (4-2A), and (4-2B),
R^{T} represents a hydrogen atom, a fluorine atom, a methyl group, or a trifluoromethyl group,
in each of the formulae (4-1A) and (4-1B),
R^{X} represents a hydrogen atom or a monovalent hydrocarbon group having 1 to 20 carbon atoms; and
R^{Y} and R^{Z} each independently represent a monovalent hydrocarbon group having 1 to 20 carbon atoms, or R^{Y} and R^{Z} taken together represent an alicyclic structure having 3 to ring atoms together with the carbon atom to which R^{Y} and R^{Z} bond, in the formula (4-1C),
R^{C} represents a hydrogen atom;
R^{D} and R^{E} each independently represent a hydrogen atom or a monovalent hydrocarbon group having 1 to 20 carbon atoms; and
R^{F} represents a divalent hydrocarbon group having 1 to 20 carbon atoms constituting an unsaturated alicyclic structure having 4 to 20 ring atoms together with the carbon atom to which each of R^{C}, R^{D}, and R^{E} bond, and
in each of the formulae (4-2A) and (4-2B),
R^{U} and R^{V} each independently represent a hydrogen atom or a monovalent hydrocarbon group having 1 to 20 carbon atoms, and R^{W} represents a monovalent hydrocarbon group having 1 to 20 carbon atoms, and optionally
R^{U} and R^{V} taken together represent an alicyclic structure having 3 to 20 ring atoms together with the carbon atom to which R^{U} and R^{V} bond, or R^{U} and R^{W} taken together represent an aliphatic heterocyclic structure having 5 to 20 ring atoms together with the carbon atom to which R^{U} bonds and the oxygen atom to which R^{W} bonds.

17. The resist pattern-forming method according to claim 11, wherein in the formula (1), R¹, R², R³, R⁴, R⁵, and R⁶ each represent a fluorine atom; and R^{A} represents a hydrogen atom.

18. The resist pattern-forming method according to claim 11, wherein the second structural unit is represented by formula (1-1) or formula (1-2): 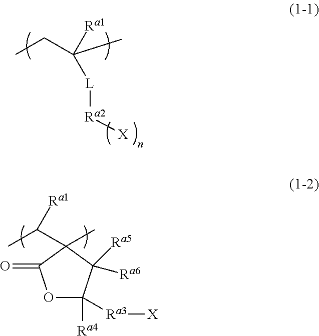
wherein in each of the formulae (1-1) and (1-2),
R^{a1} represents a hydrogen atom, a fluorine atom, a methyl group, or a trifluoromethyl group; and X represents the group represented by the formula (1),
in the formula (1-1), L represents a single bond or —COO—; R² represents a monovalent organic group having a valency of (n+1) and having 1 to 20 carbon atoms; and n is an integer of 1 to 3, wherein in a case in which n is no less than 2, a plurality of Xs are identical or different from each other, and
in the formula (1-2), R^{a2} represents a divalent hydrocarbon group having 1 to 20 carbon atoms; R^{a4} represents a monovalent hydrocarbon group having 1 to 20 carbon atoms; and R^{a5} and R^{a6} each independently represent a hydrogen atom or a monovalent hydrocarbon group having 1 to 10 carbon atoms, or R^{a5} and R^{a6} taken together represent a ring structure having 3 to 20 ring atoms, together with the carbon atom to which R^{a5} and R^{a6} bond.

19. The resist pattern-forming method according to claim 18, wherein in the formula (1), R¹, R², R³, R⁴, R⁵, and R⁶ each represent a fluorine atom; and R^{A} represents a hydrogen atom, and in the formula (1-2), R^{a2} represents an alicyclic saturated hydrocarbon group.
